(19) United States
(12) Patent Application Publication
(10) Pub. No.: US 2024/0188343 A1
(43) Pub. Date: Jun. 6, 2024

(54) DISPLAY APPARATUS AND METHOD OF MANUFACTURING THE SAME

(71) Applicant: Samsung Display Co., Ltd., Yongin-si (KR)

(72) Inventors: Junhong Park, Yongin-si (KR); Yeongwoo Kwon, Yongin-si (KR); Jeongwon Kim, Yongin-si (KR)

(73) Assignee: Samsung Display Co., Ltd., Yongin-si (KR)

(21) Appl. No.: 18/527,546

(22) Filed: Dec. 4, 2023

(30) Foreign Application Priority Data
Dec. 6, 2022 (KR) 10-2022-0169103

(51) Int. Cl. H10K 59/122; H10K 59/12; H10K 59/88

(52) U.S. Cl. CPC H10K 59/122; H10K 59/1201; H10K 59/88

(57) ABSTRACT

A display apparatus includes a first sub-pixel electrode, a second sub-pixel electrode adjacent to the first sub-pixel electrode, a metal bank layer including a first opening overlapping the first sub-pixel electrode, a second opening overlapping the second sub-pixel electrode, a first metal layer, and a second metal layer disposed on the first metal layer, wherein the metal bank layer further includes an anchor hole disposed between the first opening and the second opening.

### CROSS-REFERENCE TO RELATED APPLICATION(S)

This application claims priority to and benefits of Korean Patent Application No. 10-2022-0169103 under 35 U.S.C. § 119, filed on Dec. 6, 2022, in the Korean Intellectual Property Office, the entire contents of which are incorporated herein by reference.

### BACKGROUND

### 1. Technical Field

One or more embodiments relate to a structure of a display apparatus and a method of manufacturing the display apparatus.

### 2. Description of the Related Art

A display apparatus visually displays data. The display apparatus may include a substrate divided into a display area and a peripheral area. A scan line is insulated from a data line in the display area, and a plurality of pixels may be arranged in the display area. For example, a thin-film transistor and a sub-pixel electrode electrically connected to the thin-film transistor may be provided in the display area. Each of the thin-film transistor and the sub-pixel electrode may correspond to each of the pixels. An opposite electrode may be provided in the display area. The opposite electrode may be commonly formed in the pixels. Various wirings, a scan driver, a data driver, a controller, a pad portion, and the like, which transfer electrical signals to the display area, may be formed in the peripheral area.

The usage of display apparatuses has diversified. Accordingly, various designs have been researched to improve the quality of a display apparatus.

### SUMMARY

Embodiments provide a display apparatus that has improved resolution and is capable of implementing excellent image quality.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, a display apparatus may include a first sub-pixel electrode, a second sub-pixel electrode adjacent to the first sub-pixel electrode, a metal bank layer including a first opening overlapping the first sub-pixel electrode, a second opening overlapping the second sub-pixel electrode, a first metal layer, and a second metal layer disposed on the first metal layer, a first intermediate layer overlapping the first sub-pixel electrode through the first opening of the metal bank layer, a second intermediate layer overlapping the second sub-pixel electrode through the second opening of the metal bank layer, a first opposite electrode disposed on the first intermediate layer through the first opening of the metal bank layer, and a second opposite electrode disposed on the second intermediate layer through the second opening of the metal bank layer, wherein the metal bank layer may further include an anchor hole disposed between the first opening and the second opening.

The display apparatus may further include an organic encapsulation layer filling at least a portion of each of the first opening, the second opening, and the anchor hole.

The anchor hole may be partially removed in a thickness direction of the metal bank layer, and a depth of the anchor hole may be less than a thickness of the metal bank layer.

The anchor hole may expose an upper surface of the first metal layer that is partially removed, and the upper surface of the first metal layer exposed through the anchor hole may contact the organic encapsulation layer.

The anchor hole may pass through the metal bank layer, and a depth of the anchor hole may be substantially equal to a thickness of the metal bank layer.

The display apparatus may further include an insulating layer covering an edge portion of the first sub-pixel electrode and disposed under the metal bank layer, wherein the anchor hole may expose an upper surface of the insulating layer, and the upper surface of the insulating layer may contact the organic encapsulation layer through the anchor hole.

A portion of the second metal layer disposed around the first opening may include a tip extending from a portion at which a lower surface of the second metal layer contacts a lateral surface of the first metal layer, to the first opening, a portion of the second metal layer disposed around the second opening may include a tip extending from a portion at which the lower surface of the second metal layer contacts the lateral surface of the first metal layer, to the second opening, and a portion of the second metal layer disposed around the anchor hole may include a tip extending from a portion at which the lower surface of the second metal layer contacts the lateral surface of the first metal layer, to the anchor hole.

An outer portion of the first opposite electrode may contact a lateral surface of the first metal layer facing the first opening of the metal bank layer, and an outer portion of the second opposite electrode may contact a lateral surface of the first metal layer facing the second opening of the metal bank layer.

The display apparatus may further disposed on the metal bank layer, the first dummy intermediate layer and the first intermediate layer including a same material, a first dummy opposite electrode disposed on the first dummy intermediate layer, the first dummy opposite electrode and the first opposite electrode including a same material, and a first sub-pixel inorganic encapsulation layer covering an inner surface of the first opening, wherein the first sub-pixel inorganic encapsulation layer may continuously extend to overlap an upper surface and two opposite lateral surfaces of the first dummy opposite electrode, and two opposite lateral surfaces of the first dummy intermediate layer.

An end portion of the first sub-pixel inorganic encapsulation layer may contact a lateral surface of the metal bank layer facing the anchor hole.

The display apparatus may further include a capping layer disposed between a region between the first opposite electrode and the first sub-pixel inorganic encapsulation layer, and a region between the first dummy opposite electrode and the first sub-pixel inorganic encapsulation layer.

The display apparatus may further include a second dummy intermediate layer disposed on the metal bank layer to contact the first sub-pixel inorganic encapsulation layer, the second dummy intermediate layer and the second intermediate layer including a same material, a second dummy opposite electrode disposed on the second dummy intermediate layer, the second dummy opposite electrode and the second opposite electrode including a same material, and a second sub-pixel inorganic encapsulation layer covering an inner surface of the second opening, wherein the second sub-pixel inorganic encapsulation layer may continuously extend to overlap an upper surface and two opposite lateral surfaces of the second dummy opposite electrode, two opposite lateral surfaces of the second dummy intermediate layer, two opposite lateral surfaces of the first dummy opposite electrode, and two opposite lateral surfaces of the first dummy intermediate layer.

According to one or more embodiments, a display apparatus may include a first sub-pixel electrode, a metal bank layer including a first opening overlapping the first sub-pixel electrode, a first metal layer, and a second metal layer disposed on the first metal layer, a first intermediate layer overlapping the first sub-pixel electrode through the first opening of the metal bank layer, a first opposite electrode disposed on the first intermediate layer through the first opening of the metal bank layer, a first dummy intermediate layer disposed on the metal bank layer, the first dummy intermediate layer and the first intermediate layer including a same material, a first dummy opposite electrode disposed on the first dummy intermediate layer, the first dummy opposite electrode and the first opposite electrode including a same material, and a first sub-pixel inorganic encapsulation layer disposed on the first opposite electrode, wherein the first sub-pixel inorganic encapsulation layer may continuously extend to overlap an inner surface of the first opening, an upper surface and two opposite lateral surfaces of the first dummy opposite electrode, and two opposite lateral surfaces of the first dummy intermediate layer.

The display apparatus may further include a second sub-pixel electrode, a second intermediate layer overlapping the second sub-pixel electrode through a second opening of the metal bank layer, a second opposite electrode disposed on the second intermediate layer through the second opening of the metal bank layer, a second dummy intermediate layer disposed on the metal bank layer to contact the first sub-pixel inorganic encapsulation layer, the second dummy intermediate layer and the second intermediate layer including a same material, a second dummy opposite electrode disposed on the second dummy intermediate layer, the second dummy opposite electrode and the second opposite electrode including a same material, and a second sub-pixel inorganic encapsulation layer disposed on the second opposite electrode, wherein the second sub-pixel inorganic encapsulation layer may continuously extend to surround an inner surface of the second opening, an upper surface and two opposite lateral surfaces of the second dummy opposite electrode, two opposite lateral surfaces of the second dummy intermediate layer, two opposite lateral surfaces of the first dummy opposite electrode, and two opposite lateral surfaces of the first dummy intermediate layer.

An outer portion of the first opposite electrode may contact a lateral surface of the first metal layer facing the first opening of the metal bank layer.

A portion of the second metal layer facing the first opening of the metal bank layer may include a tip extending to the first opening from a portion at which a lower surface of the second metal layer contacts a lateral surface of the first metal layer.

The metal bank layer may further include an anchor hole disposed in a non-sub-pixel area in which the first sub-pixel electrode and the second sub-pixel electrode are not disposed, wherein the anchor hole may be disposed between the first opening and the second opening.

The display apparatus may further include an organic encapsulation layer filling at least a portion of each of the first opening, the second opening, and the anchor hole, wherein the organic encapsulation layer may be disposed on the first sub-pixel inorganic encapsulation layer and the second sub-pixel inorganic encapsulation layer.

The anchor hole may be partially removed in a thickness direction of the metal bank layer, and a depth of the anchor hole may be less than a thickness of the metal bank layer.

The anchor hole may expose an upper surface of the first metal layer that is partially removed, and the upper surface of the first metal layer exposed through the anchor hole may contact the organic encapsulation layer.

The anchor hole may pass through the metal bank layer, and a depth of the anchor hole may be substantially equal to a thickness of the metal bank layer.

The display apparatus may further include an insulating layer covering an edge portion of the first sub-pixel electrode and disposed under the metal bank layer, wherein the anchor hole may expose an upper surface of the insulating layer, and the upper surface of the insulating layer may contact the organic encapsulation layer through the anchor hole.

The display apparatus may further include a capping layer disposed in each of a region between the first opposite electrode and the first sub-pixel inorganic encapsulation layer, a region between the first dummy opposite electrode and the first sub-pixel inorganic encapsulation layer, a region between the second opposite electrode and the second sub-pixel inorganic encapsulation layer, and a region between the second dummy opposite electrode and the second sub-pixel inorganic encapsulation layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B are schematic perspective views of a display apparatus according to an embodiment;

FIGS. 2A and 2B are schematic equivalent circuit diagrams of a light-emitting diode corresponding to one of sub-pixels of the display apparatus 1 and a sub-pixel circuit connected to a relevant light-emitting diode according to an embodiment.

FIGS. 3A to 3K are schematic cross-sectional views showing states corresponding to a process of manufacturing a display apparatus according to an embodiment;

FIG. 3L is a schematic cross-sectional view of a stack structure of a light-emitting diode according to an embodiment;

FIG. 4 is a schematic cross-sectional view of a display apparatus according to an embodiment;

FIG. 5 is a schematic plan view of a light-emitting diode and an anchor hole of a display apparatus according to an embodiment;

FIGS. 6A to 6W are schematic cross-sectional views showing a process of manufacturing a display apparatus according to an embodiment; and

FIG. 7 is a schematic cross-sectional view of a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein.

It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

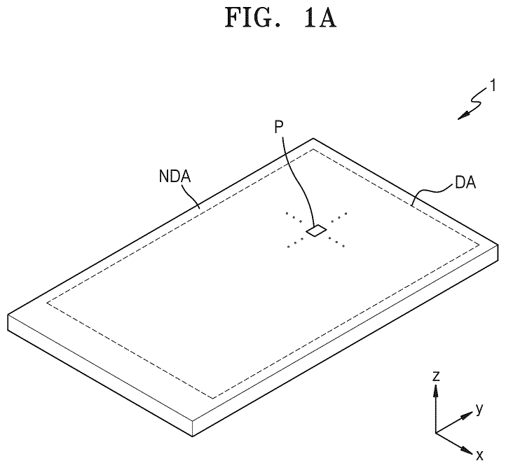

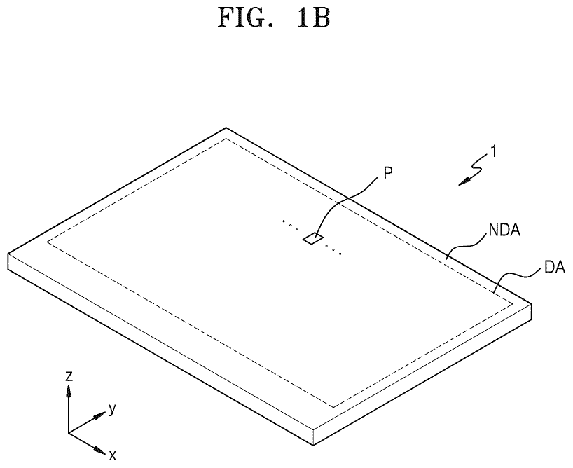

FIGS. 1A and 1B are schematic perspective views of a display apparatus 1 according to an embodiment.

Referring to FIGS. 1A and 1B, the display apparatus 1 may include a display area DA and a non-display area NDA outside the display area DA. The display area DA may display images through sub-pixels P arranged in the display area DA. The non-display area NDA is arranged outside the display area DA and does not display images. The non-display area NDA may surround (e.g., entirely surround) the display area DA. A driver and the like, which provide electrical signals or power to the display area DA, may be arranged in the non-display area NDA. A pad may be arranged in the non-display area NDA. The pad may be a region to which electronic elements or a printed circuit board may be electrically connected.

In an embodiment, although FIG. 1A shows that the display area DA is a polygon (e.g., a quadrangle) in which a length thereof in an x-axis direction is less than a length thereof in a y-axis direction, FIG. 1B shows that the display area DA is a polygon (e.g., a quadrangle) in which a length thereof in the y-axis direction is less than a length thereof in the x-axis direction in an embodiment. Although FIGS. 1A and 1B show the display area DA is an approximately quadrangle, embodiments are not limited thereto. As an embodiment, the display area DA may have various shapes such as an N-gon, where N is a natural number of 3 or more, a circle, or an ellipse. Although it is shown in FIGS. 1A and 1B that the display area DA has a shape in which a corner of the display area DA includes a vertex at which a straight line meets a straight line, the display area DA may have a polygon having round corners.

Hereinafter, for convenience of description, although the case where the display apparatus 1 is a smartphone is described, the display apparatus 1 according to an embodiment is not limited thereto. The display apparatus 1 may be applicable to various products including televisions, notebook computers, monitors, advertisement boards, Internet of things (IoTs) as well as portable electronic apparatuses including mobile phones, smart phones, tablet personal computers (PCs), mobile communication terminals, electronic organizers, electronic books, portable multimedia players (PMPs), navigations, and ultra mobile personal computers (UMPCs). For example, the display apparatus 1 according to an embodiment may be applicable to wearable devices including smartwatches, watchphones, glasses-type displays, and head-mounted displays (HMDs). For example, in an embodiment, the display apparatus 1 may be applicable to a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles.

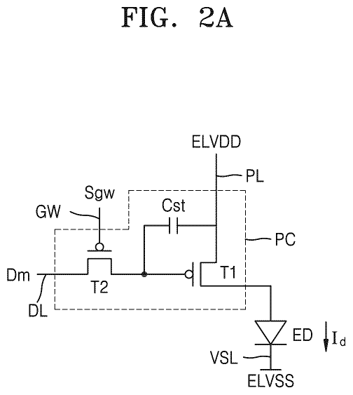

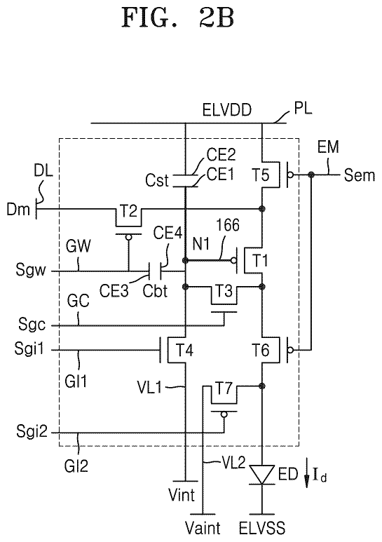

FIGS. 2A and 2B are schematic equivalent circuit diagrams of a light-emitting diode corresponding to one of sub-pixels of the display apparatus 1 and a sub-pixel circuit connected to a relevant light-emitting diode according to an embodiment.

Referring to FIG. 2A, a light-emitting diode ED may be electrically connected to a sub-pixel circuit PC, and the sub-pixel circuit PC may include a first transistor T1, a second transistor T2, and a storage capacitor Cst. A sub-pixel electrode (e.g., an anode) of the light-emitting diode ED may be electrically connected to the first transistor T1, and an opposite electrode (e.g., a cathode) may be electrically connected to an auxiliary line VSL and may receive a voltage corresponding to a common voltage ELVSS through the auxiliary line VSL.

The second transistor T2 may transfer a data signal Dm to the first transistor T1 according to a scan signal Sgw input through a scan line GW. The data signal Dm may be input through a data line DL.

The storage capacitor Cst may be connected to the second transistor T2 and a driving voltage line PL and may store a voltage corresponding to a difference between a voltage transferred from the second transistor T2 and a driving voltage ELVDD supplied to the driving voltage line PL.

The first transistor T1 may be connected to the driving voltage line PL and the storage capacitor Cst and may control a driving current Id according to the voltage stored in the storage capacitor Cst, the driving current Id flowing from the driving voltage line PL to the light-emitting diode ED. The light-emitting diode ED may emit light having a certain brightness corresponding to the driving current Id.

Although it is described with reference to FIG. 2A that the sub-pixel circuit PC includes two transistors and one storage capacitor, embodiments are not limited thereto.

FIG. 2A is a schematic equivalent circuit diagram of a light-emitting diode corresponding to one of sub-pixels of the display apparatus 1 and a sub-pixel circuit connected to a relevant light-emitting diode according to an embodiment.

Referring to FIG. 2B, the sub-pixel circuit PC may include seven transistors and two capacitors.

The sub-pixel circuit PC may include first to seventh transistors T1, T2, T3, T4, T5, T6, and T7, a storage capacitor Cst, and a boost capacitor Cbt. In an embodiment, the sub-pixel circuit PC may not include the boost capacitor Cbt. A sub-pixel electrode (e.g., an anode) of the light-emitting diode ED may be electrically connected to the first transistor T1 through the sixth transistor T6, and an opposite electrode (e.g., a cathode) may be electrically connected to the auxiliary line VSL and may receive a voltage corresponding to the common voltage ELVSS through the auxiliary line VSL.

Some of the transistors T1, T2, T3, T4, T5, T6, and T7 may be n-channel metal oxide semiconductor (NMOS) field-effect transistors (n-channel MOSFETs), and the remaining transistors may be p-channel metal oxide semiconductor (PMOS) field-effect transistors (p-channel MOSFETs). In an embodiment, as shown in FIG. 2B, the third and fourth transistors T3 and T4 may be n-channel MOSFETs, and the remaining transistors may be p-channel MOSFETs. As an example, the third and fourth transistors T3 and T4 may be n-channel MOSFETs including an oxide-based semiconductor material, and the remaining transistors may be p-channel MOSFETs including a silicon-based semiconductor material. In an embodiment, the third, fourth, and seventh transistors T3, T4, and T7 may be n-channel MOSFETs, and the remaining transistors may be p-channel MOSFETs.

The first to seventh transistors T1, T2, T3, T4, T5, T6, and T7, the storage capacitor Cst, and the boost capacitor Cbt may be connected to signal lines. The signal lines may include an emission control line EM, a compensation gate line GC, a first initialization gate line GI1, a second initialization gate line GI2, and the data line DL. The sub-pixel circuit PC may be electrically connected to a voltage line, for example, the driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL through the fifth transistor T5, and a second electrode of the first transistor T1 may be electrically connected to a first electrode (e.g., an anode) of the light-emitting diode ED through the sixth transistor T6. One of the first electrode and the second electrode of the first transistor T1 may be a source electrode, and another one may be a drain electrode. The first transistor T1 may supply the driving current Id to the light-emitting diode ED according to a switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be connected to the driving first electrode of the first transistor T1 and electrically connected to the driving voltage line PL through the fifth transistor T5. One of the first electrode and the second electrode of the second transistor T2 may be a source electrode, and another one may be a drain electrode. The second transistor T2 may be turned on according to a scan signal Sgw transferred through the scan line GW and may perform a switching operation of transferring a data signal Dm to the first electrode of the first transistor T1. The data signal Dm may be transferred through the data line DL.

The third transistor T3 may be a compensation transistor that compensates for a threshold voltage of the first transistor T1. A third gate electrode of the third transistor T3 may be connected to a compensation gate line GC. A first electrode of the third transistor T3 may be connected to a lower electrode CE1 of the storage capacitor Cst through a node connection line 166, and connected to the first gate electrode of the first transistor T1. A first electrode of the third transistor T3 may be connected to the fourth transistor T4. A second electrode of the third transistor T3 may be connected to the second electrode of the first transistor T1 and electrically connected to the first electrode (e.g., the anode) of the light-emitting diode ED through the sixth transistor T6. One of the first electrode and the second electrode of the third transistor T3 may be a source electrode, and another one may be a drain electrode.

The third transistor T3 may be turned on according to a compensation signal Sgc transferred through the compensation gate line GC, and diode-connects the first transistor T1 by electrically connecting the first gate electrode to the second electrode (e.g., a drain electrode) of the first transistor T1.

The fourth transistor T4 may be a first initialization transistor that initializes the first gate electrode of the first transistor T1. A fourth gate electrode of the fourth transistor T4 may be connected to a first initialization gate line GI1. A first electrode of the fourth transistor T4 may be connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and another one may be a drain electrode. The fourth transistor T4 may be turned on according to a first initialization signal Sgi1 transferred through the first initialization gate line GI1 and may perform an initialization operation of initializing the voltage of the first gate electrode of the first transistor T1 by transferring a first initialization voltage Vint to the first gate electrode of the driving transistor T1.

The fifth transistor T5 may be an operation control transistor. A fifth gate electrode of the fifth transistor T5 may be connected to the emission control line EM, a first electrode of the fifth transistor T5 may be connected to the driving voltage line PL, and a second electrode of the fifth transistor T5 may be connected to the first electrode of the first transistor T1 and the second electrode of the second transistor T2. One of the first electrode and the second electrode of the fifth transistor T5 may be a source electrode, and another one may be a drain electrode.

The sixth transistor T6 may be an emission control transistor. A sixth gate electrode of the sixth transistor T6 may be connected to the emission control line EM, a first electrode of the sixth transistor T6 may be connected to the second electrode of the first transistor T1 and the second electrode of the third transistor T3, and a second electrode of the sixth transistor T6 may be electrically connected to a second electrode of the seventh transistor T7 and the first electrode (e.g., the anode) of the light-emitting diode ED. One of the first electrode and the second electrode of the sixth transistor T6 may be a source electrode, and another one may be a drain electrode.

The fifth transistor T5 and the sixth transistor T6 may be simultaneously turned on according to an emission control signal Sem transferred through the emission control line EM, the driving voltage ELVDD may be transferred to the light-emitting diode ED, and the driving current I_{d} may flow through the light-emitting diode ED.

The seventh transistor T7 may be a second initialization transistor that initializes the first electrode of the light-emitting diode ED. A seventh gate electrode of the seventh transistor T7 may be connected to a second initialization gate line GI2. A first electrode of the seventh transistor T7 may be connected to the second initialization voltage line VL2. A second electrode of the seventh transistor T7 may be connected to the second electrode of the sixth transistor T6 and the first electrode (e.g., the anode) of the light-emitting diode ED. The seventh transistor T7 may be turned on according to a second initialization signal Sgi2 transferred through the second initialization gate line GI2, and may initialize the first electrode of the light-emitting diode ED by transferring a second initialization voltage Vaint to the first electrode (e.g., the anode) of the light-emitting diode ED.

In an embodiment, the second initialization voltage line VL2 may be a next scan line. As an example, the second initialization gate line GI2 connected to the seventh transistor T7 of the sub-pixel circuit PC and arranged in an i-th row, may correspond to a scan line of the sub-pixel circuit PC arranged in an (i+1)-th row, where i is a natural number. In an embodiment, the second initialization voltage line VL2 may be the emission control line EM. As an example, the emission control line EM may be electrically connected to the fifth to seventh transistors T5, T6, and T7.

The storage capacitor Cst may include the lower electrode CE1 and an upper electrode CE2. The lower electrode CE1 of the storage capacitor Cst may be connected to the first gate electrode of the first transistor T1, and the upper electrode CE2 of the storage capacitor Cst may be connected to the driving voltage line PL. The storage capacitor Cst may store charge corresponding to a difference between a voltage of the first gate electrode of the first transistor T1 and the driving voltage ELVDD.

The boost capacitor Cbt may include a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. The boost capacitor Cbt may raise the voltage of a first node N1 in case that a scan signal Sgw supplied to the scan line GW is turned off. In case that the voltage of the first node N1 is raised, a black grayscale may be clearly expressed.

The first node N1 may be a region where the first gate electrode of the first transistor T1, the first electrode of the third transistor T3, the second electrode of the fourth transistor T4, and the fourth electrode CE4 of the boost capacitor Cbt are connected to each other.

In an embodiment, it is described in FIG. 2B that the third and fourth transistors T3 and T4 are n-channel MOSFETs, and the first, second, fifth to seventh transistors T1, T2, T5, T6, and T7 are p-channel MOSFETs. The first transistor T1 directly influencing the brightness of the display apparatus displaying images may include a semiconductor layer including polycrystalline silicon having high reliability, and thus, a high-resolution display apparatus may be implemented through this configuration.

Although it is described in FIG. 2B that some of the transistors are NMOSFETs and the remaining transistors are PMOSFETs, embodiments are not limited thereto. In an embodiment, the sub-pixel circuit PC may include three transistors and all of the three transistors may be NMOSFETs. However, various modifications may be made.

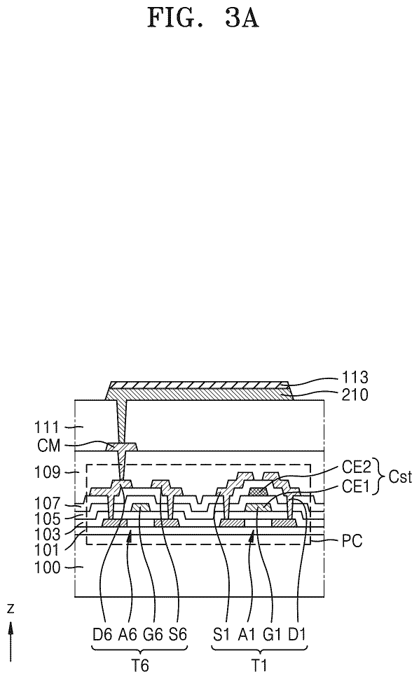

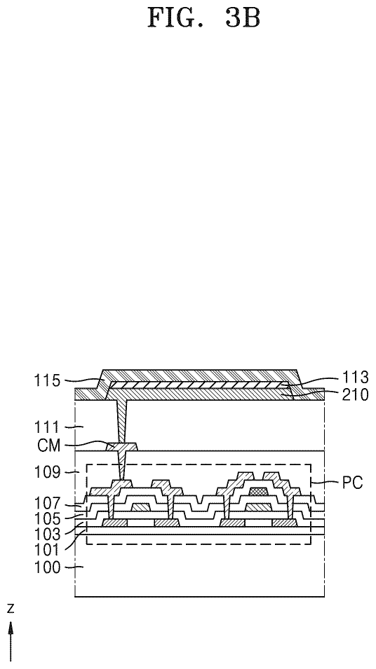

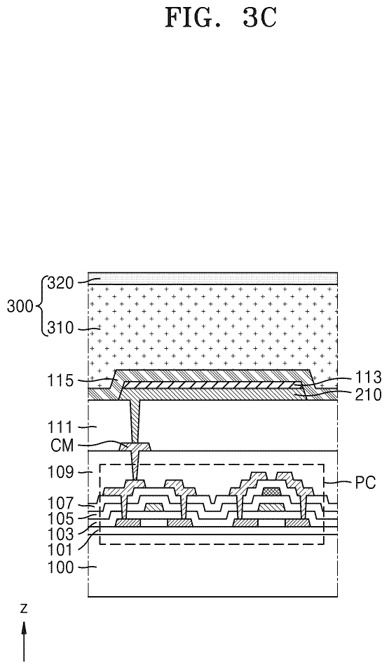

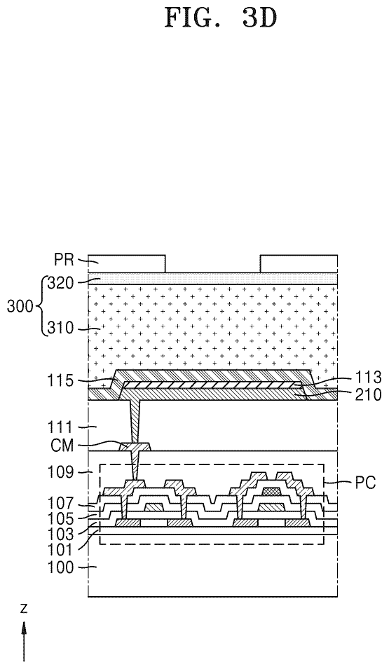

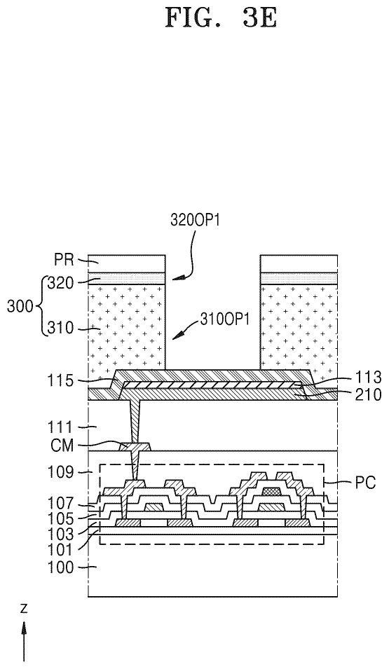

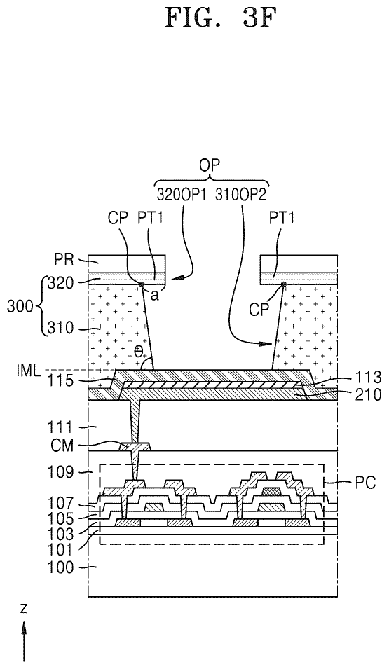

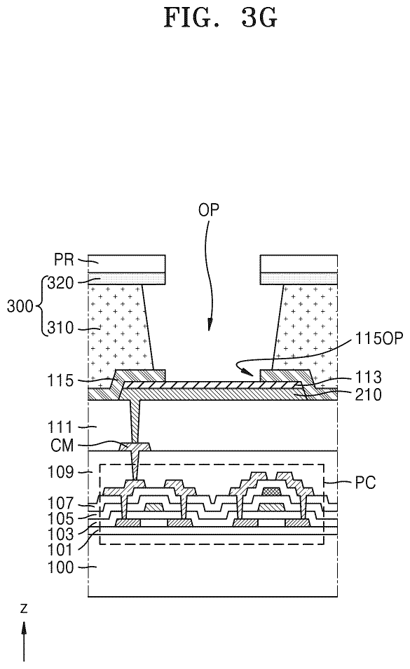

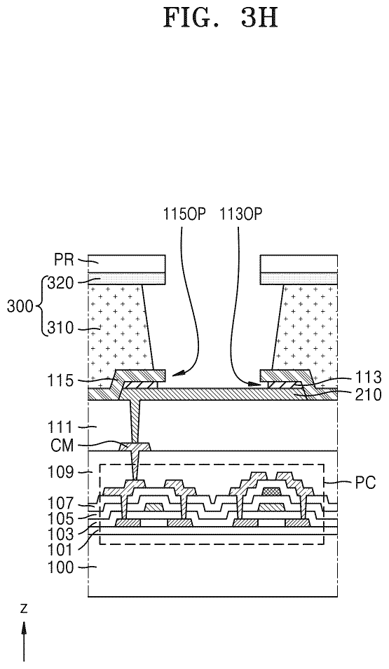

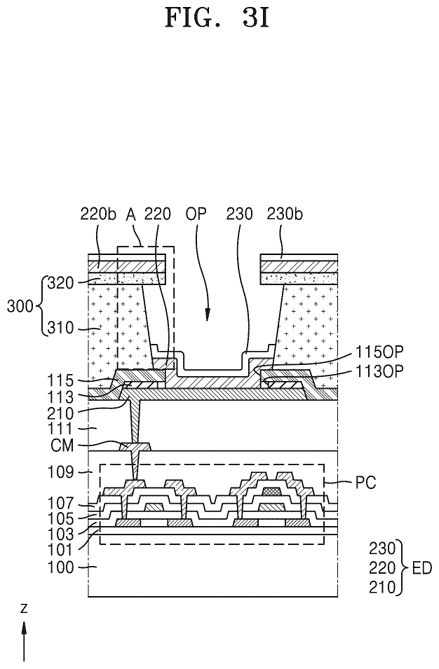

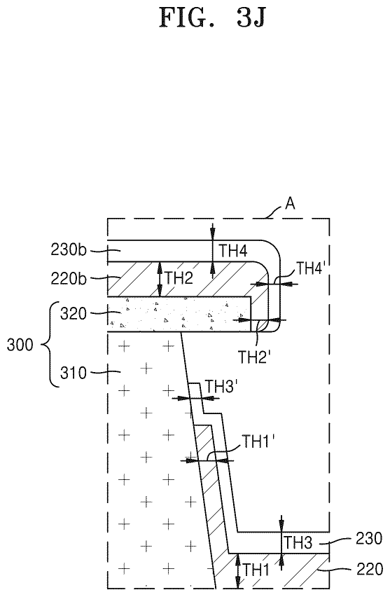

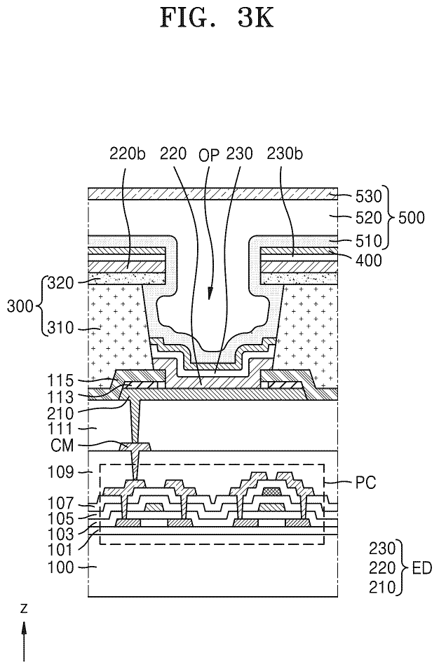

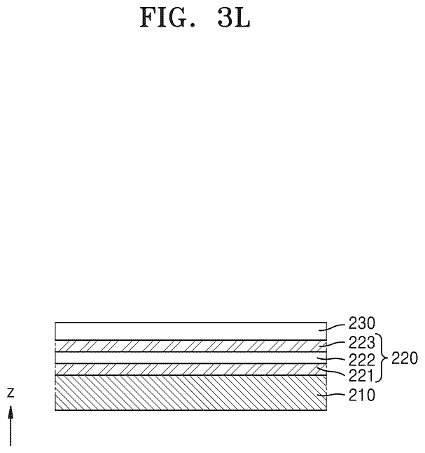

FIGS. 3A to 3K are schematic cross-sectional views showing states corresponding to a process of manufacturing the display apparatus 1 according to an embodiment, and FIG. 3L is a schematic cross-sectional view of a stack structure of a light-emitting diode according to an embodiment.

Referring to FIG. 3A, the sub-pixel circuit PC may be formed on a substrate 100. The substrate 100 may include glass or polymer resin. The substrate 100 may have a structure in which a base layer including polymer resin and an inorganic barrier layer are stacked. The polymer resin may include a polymer resin such as polyethersulphone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose tri acetate (TAC), cellulose acetate propionate (CAP), and the like.

A buffer layer 101 may be disposed on the upper surface of the substrate 100. The buffer layer 101 may prevent impurities from penetrating a semiconductor layer of a transistor. The buffer layer 101 may include an inorganic insulating material such as silicon nitride, silicon oxynitride, and silicon oxide, and include a single layer or a multi-layer including the above inorganic insulating materials.

The sub-pixel circuit PC may be disposed on the buffer layer 101. As described above with reference to FIG. 2A or 2B, the sub-pixel circuit PC may include the transistors and the storage capacitor. In an embodiment, FIG. 3A shows the first transistor T1, the sixth transistor T6, and the storage capacitor Cst of the sub-pixel circuit PC.

The first transistor T1 may include a first semiconductor layer A1 and a first gate electrode G1. The first semiconductor layer A1 may be on the buffer layer 101, and the first gate electrode G1 may overlap a channel region of the first semiconductor layer A1. The first semiconductor layer A1 may include a silicon-based semiconductor material, for example, polycrystalline silicon. The first semiconductor layer A1 may include a channel region, a first region, and a second region, the first region and the second region being on two opposite sides of the channel region. The first region and the second region may be regions including impurities of higher concentration than that of the channel region. One of the first region and the second region may correspond to a source region, and another one may correspond to a drain region.

The sixth transistor T6 may include a sixth semiconductor layer A6 and a sixth gate electrode G6. The sixth semiconductor layer A6 may be on the buffer layer 101, and the sixth gate electrode G6 may overlap a channel region of the sixth semiconductor layer A6. The sixth semiconductor layer A6 may include a silicon-based semiconductor material, for example, polycrystalline silicon. The sixth semiconductor layer A6 may include a channel region, a first region, and a second region, the first region and the second region being on two opposite sides of the channel region. The first region and the second region may be regions including impurities of higher concentration than that of the channel region. One of the first region and the second region may correspond to a source region, and another one may correspond to a drain region.

The first gate electrode G1 and the sixth gate electrode G6 may include a conductive material including molybdenum (Mo), aluminum (Al), copper (Cu), and titanium (Ti) and have a single-layered structure or a multi-layered structure including the above materials. A first gate insulating layer 103 may be disposed below the first gate electrode G1 and the sixth gate electrode G6. The first gate insulating layer 103 may be for electrical insulation between the first semiconductor layer A1 and the first gate electrode G1 and between the sixth semiconductor layer A6 and the sixth gate electrode G6. The first gate insulating layer 103 may include an inorganic insulating material such as silicon nitride, silicon oxynitride, and silicon oxide, and include a single layer or a multi-layer including the above inorganic insulating materials.

The storage capacitor Cst may include the lower electrode CE1 and the upper electrode CE2 overlapping each other. In an embodiment, the lower electrode CE1 of the storage capacitor Cst may include the first gate electrode G1. For example, the first gate electrode G1 may include the lower electrode CE1 of the storage capacitor Cst. As an example, the first gate electrode G1 and the lower electrode CE1 of the storage capacitor Cst may be a single body.

A first interlayer insulating layer 105 may be disposed between the lower electrode CE1 and the upper electrode CE2 of the storage capacitor Cst. The first interlayer insulating layer 105 may include an inorganic insulating material such as silicon nitride, silicon oxynitride, and silicon oxide, and include a single-layered structure or a multi-layered structure including the above inorganic insulating materials.

The upper electrode CE2 of the storage capacitor Cst may include a conductive material of a low-resistance material such as molybdenum (Mo), aluminum (Al), copper (Cu) and/or titanium (Ti), and have a single-layered structure or a multi-layered structure including the above materials.

A second interlayer insulating layer 107 may be disposed on the storage capacitor Cst. The second interlayer insulating layer 107 may include an inorganic insulating material such as silicon nitride, silicon oxynitride, and silicon oxide, and include a single-layered structure or a multi-layered structure including the above inorganic insulating materials.

A source electrode S1 and/or a drain electrode D1 may be disposed on the second interlayer insulating layer 107. The source electrode S1 and/or the drain electrode D1 may be connected (e.g., electrically connected) to the first semiconductor layer A1 of the first transistor T1. A source electrode S6 and/or a drain electrode D6 may be disposed on the second interlayer insulating layer 107. The source electrode S6 and/or the drain electrode D6 may be connected (e.g., electrically connected) to the sixth semiconductor layer A6 of the sixth transistor T6. The source electrodes S1 and S6 and/or the drain electrodes D1 and D6 may include aluminum (Al), copper (Cu), and/or titanium (Ti), and may include a single layer or a multi-layer including the above materials.

A first organic insulating layer 109 may be disposed on the sub-pixel circuit PC. The first organic insulating layer 109 may include an organic insulating material such as acryl, benzocyclobutene (BCB), polyimide, or hexamethyldisiloxane (HMDSO).

A connection metal CM may be disposed on the first organic insulating layer 109. The connection metal CM may include aluminum (Al), copper (Cu), and/or titanium (Ti), and include a single layer or a multi-layer including the above materials.

A second organic insulating layer 111 may be disposed between the connection metal CM and the sub-pixel electrode 210. The second organic insulating layer 111 may include an organic insulating material such as acryl, benzocyclobutene (BCB), polyimide, or hexamethyldisiloxane (HMDSO). According to an embodiment described with reference to FIG. 3A, although the sub-pixel circuit PC is electrically connected to the sub-pixel electrode 210 through the connection metal CM, the connection metal CM may be omitted and an organic insulating layer (or a single organic insulating layer) may be positioned between the sub-pixel circuit PC and the sub-pixel electrode 210 according to an embodiment. For example, three or more organic insulating layers may be positioned between the sub-pixel circuit PC and the sub-pixel electrode 210. The sub-pixel circuit PC may be electrically connected to the sub-pixel electrode 210 through connection metals.

The sub-pixel electrode 210 may be formed on the second organic insulating layer 111. The sub-pixel electrode 210 may be formed to be a transparent electrode (or a semi-transparent electrode) or formed to be a reflective electrode. In the case where the sub-pixel electrode 210 is formed to be a transparent electrode (or a semi-transparent electrode), the sub-pixel electrode 210 may include indium tin oxide (ITO), indium zinc oxide (IZO), zinc oxide (ZnO), indium oxide (In₂O₃), indium gallium oxide (IGO), or aluminum zinc oxide (AZO). In the case where the sub-pixel electrode 210 is formed to be a reflective electrode, the sub-pixel electrode 210 may include a reflective layer including Ag, Mg, Al, Pt, Pd, Au, Ni, Nd, Ir, Cr, or a compound thereof, and a layer disposed on the reflective layer, the layer including ITO, IZO, ZnO or In₂O₃. In an embodiment, the sub-pixel electrode 210 may have a structure of an ITO layer, an Ag layer, and an ITO layer that are sequentially stacked. The sub-pixel electrode 210 may be electrically connected to the connection metal CM through a contact hole of the second organic insulating layer 111.

A protective layer 113 may be formed on the sub-pixel electrode 210. The protective layer 113 may be formed together with the sub-pixel electrode 210. As an example, the sub-pixel electrode 210 and the protective layer 113 may be formed by using the same mask. The protective layer 113 may prevent the sub-pixel electrode 210 from being damaged by a gas, a liquid material, or the like used in various etching processes or ashing processes included in the process of manufacturing the display apparatus. The protective layer 113 may include a conductive oxide such as indium tin oxide (ITO), indium zinc oxide (IZO), indium gallium zinc oxide (IGZO), indium tin zinc oxide (ITZO), zinc oxide (ZnO), aluminum doped zinc oxide (AZO), gallium doped zinc oxide (GZO), zinc tin oxide (ZTO), gallium tin oxide (GTO), and fluorine doped tin oxide (FTO).

Referring to FIG. 3B, an insulating layer 115 may be formed on the structure shown in FIG. 3A. The insulating layer 115 may be formed (e.g., entirely formed) on the substrate 100. As an example, the insulating layer 115 may overlap the sub-pixel electrode 210 and the protective layer 113 and contact (e.g., directly contact) the upper surface of the second organic insulating layer 111 where the sub-pixel electrode 210 and the protective layer 113 are not formed or present. The insulating layer 115 may cover the lateral surface of each of the sub-pixel electrode 210 and the protective layer 113. The insulating layer 115 may include an inorganic insulating material. In the case where the insulating layer 115 includes an inorganic insulating material, the quality of the light-emitting diode may be prevented or reduced from being deteriorated by a gas emitted from an insulating layer, which is an organic insulating material, during the process of manufacturing the display apparatus compared to the case where the insulating layer 115 includes an organic insulating material.

The insulating layer 115 may include an inorganic insulating material such as silicon nitride, silicon oxynitride, and silicon oxide, and include a single-layered structure or a multi-layered structure including the above inorganic insulating materials. In an embodiment, the insulating layer 115 may have a two-layered structure of a silicon oxide layer and a silicon nitride layer. The thickness of the silicon oxide layer may be less than the thickness of the silicon nitride layer. In an embodiment, the thickness of the insulating layer 115 may be less than the thickness of the protective layer 113. As an example, although the thickness of the insulating layer 115 may be about 1,000 Å, and the thickness of the protective layer 113 may be about 500 Å, but embodiments are not limited thereto.

Referring to FIG. 3C, a metal bank layer 300 may be formed on the insulating layer 115 shown in FIG. 3B. The metal bank layer 300 may include a first metal layer 310 and a second metal layer 320 on the first metal layer 310.

The first metal layer 310 and the second metal layer 320 may include different metals. As an example, the first metal layer 310 and the second metal layer 320 may include metals having different etching selectivities. In an embodiment, the first metal layer 310 may include a layer including aluminum (Al), and the second metal layer 320 may include a layer including titanium (Ti).

The thickness of the first metal layer 310 may be greater than the thickness of the second metal layer 320. In an embodiment, the thickness of the first metal layer 310 may be greater than about 5 times the thickness of the second metal layer 320. In an embodiment, the thickness of the first metal layer 310 may be greater than about 6 times, greater than about 7 times, or greater than about 8 times the thickness of the second metal layer 320. In an embodiment, the thickness of the first metal layer 310 may be about 4,000 Å to about 8,000 Å, and the thickness of the second metal layer 320 may be about 500 Å to about 800 Å. The thickness of the first metal layer 310 may be about 4 times or more, about 5 times or more, or about 6 times or more of the thickness of the insulating layer 115.

Referring to FIG. 3D, a photoresist PR may be formed on the metal bank layer 300. The photoresist PR may include an opening overlapping the sub-pixel electrode 210 and the protective layer 113. A portion of the upper surface of the metal bank layer 300 may be exposed through the opening of the photoresist PR.

Referring to FIG. 3E, a portion of the metal bank layer 300, for example, a portion of the second metal layer 320 and a portion of the first metal layer 310 may be removed by using the photoresist PR as a mask. As an example, a portion of the second metal layer 320 and a portion of the first metal layer 310 may be sequentially removed through the opening of the photoresist PR. A portion of the second metal layer 320 and a portion of the first metal layer 310 may be removed by an etching process (e.g., a dry etching process). During the etching process, the insulating layer 115 and the protective layer 113 may protect the sub-pixel electrode thereunder.

By the etching process, an opening 320OP1 may be formed in the second metal layer 320. The opening 320OP1 may overlap the sub-pixel electrode 210 and the protective layer 113 and may pass through the bottom surface (or lower surface) from the upper surface of the second metal layer 320. An opening 310OP1 may be formed in the first metal layer 310. The opening 310OP1 may overlap the sub-pixel electrode 210 and the protective layer 113 and may pass through the bottom surface (or lower surface) from the upper surface of the first metal layer 310.

Referring to FIG. 3F, an opening having an undercut shape may be formed in the metal bank layer 300 by using the photoresist PR as a mask.

As an example, a portion of the first metal layer 310 may be further etched by using the photoresist PR as a mask, and an opening 310OP2 may be formed in the first metal layer 310. The opening 310OP2 may have a width greater than the width of the opening 310OP1 of the first metal layer 310 formed in the process of FIG. 3E. In an embodiment, the opening 310OP2 of the first metal layer 310 may have a shape reducing toward the lower portion. As an example, the width of the upper portion of the opening 310OP2 of the first metal layer 310 may be greater than the width of the lower portion. For example, the lateral surface of the first metal layer 310 facing the opening 310OP2 may include a slope surface tapered forward.

In an embodiment, the opening OP having an undercut shape may be formed in the metal bank layer 300 by an etching process (e.g., a wet etching process). As an example, the opening 310OP2 of the first metal layer 310 may be formed through the wet etching process. As the first metal layer 310 and the second metal layer 320 include metals having different etching selectivities, a portion of the first metal layer 310 may be removed during the wet etching process, and the opening 310OP2 of the first metal layer 310 having a width greater than the width of the opening 320OP1 of the second metal layer 320 may be formed. During the dry etching process of forming the opening 310OP2 of the first metal layer 310, the insulating layer 115 and the protective layer 113 may protect the sub-pixel electrode 210 thereunder.

As the opening 310OP2 of the first metal layer 310 has a large diameter and overlaps the opening 320OP1 of the second metal layer 320, the second metal layer 320 may have a first tip PT1.

A portion of the second metal layer 320 defining (or forming) the opening 320OP1 of the second metal layer 320 may protrude to the opening 320OP1 from a point (or portion) CP at which the lateral surface of the first metal layer 310 facing the opening 310OP2 of the first metal layer 310 is in contact with the bottom surface (or lower surface) of the second metal layer 320 and may form an undercut structure. A portion of the second metal layer 320 further protruding to the opening 320OP1 may correspond to the first tip PT1. The length of the first tip PT1, for example, a length “a” from the point (or portion) CP to the edge portion (or the lateral surface) of the first tip PT1 may be 2 μm or less. In an embodiment, the length of the first tip PT1 of the second metal layer 320 may be about 0.3 μm to about 1 μm or about 0.3 μm to about 0.7 μm.

A tapered slope angle of the lateral surface of the first metal layer 310 (e.g., a slope angle of the lateral surface of the first metal layer 310 with respect to a virtual line IML parallel to the upper surface of the substrate 100) facing the opening 310OP2 of the first metal layer 310 may be equal to or greater than about 600 and less than about 90°.

Referring to FIG. 3G, a portion of the insulating layer 115 may be removed by using the photoresist PR as a mask. A portion of the insulating layer 115 may be removed by an etching process (e.g., a dry etching process). The width of an opening 1150P of the insulating layer may be substantially the same as the width of the opening area of the photoresist PR and/or the width of the upper side of the opening OP of the metal bank layer 300 (e.g., the width of the opening 320OP1 of the second metal layer 320).

As an example, the width of the opening 1150P of the insulating layer 115 may be less than the width of the lower portion of the first metal layer 310. The lower portion (e.g., a point (or portion) at which the lateral surface of the first metal layer 310 is in contact with the bottom surface) of the lateral surface of the first metal layer 310 may be in contact with the upper surface of the insulating layer 115.

Referring to FIG. 3H, a portion of the protective layer 113 may be removed by using the photoresist PR as a mask. A portion of the protective layer 113 may be removed by using an etching process (e.g., a wet etching process), and the sub-pixel electrode 210 may be exposed through an opening 1130P of the protective layer 113. As a portion of the protective layer 113 is removed, the width of the opening 1130P of the protective layer 113 may be greater than the width of the opening 1150P of the insulating layer 115. For example, the edge portion (or the lateral surface) of the protective layer 113 defining the opening 1130P of the protective layer 113 may be positioned under the insulating layer 115.

For example, the photoresist PR may be removed.

Referring to FIG. 3I, an intermediate layer 220 and an opposite electrode 230 may be formed on the structure of FIG. 3H from which the photoresist PR is removed, to overlap the sub-pixel electrode 210. A stack structure of the sub-pixel electrode 210, the intermediate layer 220, and the opposite electrode 230 may correspond to (or overlap) the light-emitting diode ED.

In an embodiment, the intermediate layer 220 and the opposite electrode 230 may each be formed by deposition methods such as a thermal deposition.

The intermediate layer 220 may include an emission layer 222 as shown in FIG. 3L.

The intermediate layer 220 may include a common layer disposed between the sub-pixel electrode 210 and the emission layer 222 and/or between the emission layer 222 and the opposite electrode 230. Hereinafter, a common layer disposed between the sub-pixel electrode 210 and the emission layer 222 is referred to as a first common layer 221, and a common layer the emission layer 222 and the opposite electrode 230 is referred to as a second common layer 223.

The emission layer 222 may include a polymer organic material or a low-molecular weight organic material emitting light having a certain color (red, green, or blue). In an embodiment, the emission layer 222 may include an inorganic material or quantum dots.

The first common layer 221 may include a hole transport layer (HTL) and/or a hole injection layer (HIL). The second common layer 223 may include an electron transport layer (ETL) and/or an electron injection layer (EIL). The first common layer 221 and the second common layer 223 may each include an organic material.

The intermediate layer 220 may have a single stack structure including a single emission layer, or a tandem structure, which is a multi-stack structure including emission layers. In the case where the intermediate layer 220 has a tandem structure, a charge generation layer CGL may be disposed between the stacks.

The opposite electrode 230 may include a conductive material having a low work function. As an example, the opposite electrode 230 may include a transparent layer (or a semi-transparent layer) including silver (Ag), magnesium (Mg), aluminum (Al), platinum (Pt), palladium (Pd), gold (Au), nickel (Ni), neodymium (Nd), and iridium (Ir), chromium (Cr), lithium (Li), calcium (Ca), or an alloy thereof. In another example, the opposite electrode 230 may further include a layer disposed on the transparent layer (or a semi-transparent layer), the layer including ITO, IZO, ZnO, or In₂O₃.

Referring to FIG. 3I again, the intermediate layer 220 may overlap and contact the sub-pixel electrode 210 through the opening OP of the metal bank layer 300, the opening 1150P of the insulating layer 115, and the opening 1130P of the protective layer 113. The width of the emission area of the light-emitting diode ED may be substantially the same as the width of the opening 1150P of the insulating layer 115.

As the intermediate layer 220 and the opposite electrode 230 are deposited without a separate mask, a deposition material for forming the intermediate layer 220 and a deposition material for forming the opposite electrode 230 may form a dummy intermediate layer 220b and a dummy opposite electrode 230b on the metal bank layer 300. The intermediate layer 220 may be separated and spaced apart from the dummy intermediate layer 220b, and the opposite electrode 230 may be separated and spaced apart from the dummy opposite electrode 230b. The intermediate layer 220 and the dummy intermediate layer 220b may include the same material and/or the same number of sub-layers (e.g., a first common layer, an emission layer, and a second common layer). The opposite electrode 230 and the dummy opposite electrode 230b may include the same material. However, in an embodiment, the dummy intermediate layer 220b and the dummy opposite electrode 230b may be disposed not only on the second metal layer 320 but may cover the lateral surface of the second metal layer 320. FIG. 3J is an enlarged schematic view of a region A of FIG. 3I. As in FIG. 3J, the outer portion of the dummy intermediate layer 220b may extend to cover the lateral surface of the second metal layer 320 facing the opening OP. For example, the outer portion of the dummy opposite electrode 230b may be disposed on the dummy intermediate layer 220b and may extend to overlap the lateral surface of the second metal layer 320 facing the opening OP.

The edge portion or outer portion (or neighboring portion) of the opposite electrode 230 may extend beyond the edge portion or outer portion (or neighboring portion) of the intermediate layer 220 and contact (e.g., directly contact) the lateral surface of the first metal layer 310. The first metal layer 310 may be connected (e.g., electrically connected) to the opposite electrode 230. In the description, the “outer portion (or neighboring portion)” of the opposite electrode 230 denotes a “portion of the opposite electrode 230 including the edge portion of the opposite electrode 230”.

For example, the outer portions of the intermediate layer 220, the dummy intermediate layer 220b, the opposite electrode 230, and the dummy opposite electrode 230b may respectively have thinner thicknesses than the central portions thereof. For example, a thickness TH1′ of the outer portion of the intermediate layer 220 contacting (e.g., directly contacting) the lateral surface of the first metal layer 310 may be equal to or less than a half of a thickness TH1 of the central portion of the intermediate layer 220 contacting (e.g., directly contacting) the upper surface of the sub-pixel electrode 210. A thickness TH2′ of the outer portion of the dummy intermediate layer 220b contacting (e.g., directly contacting) the lateral surface of the second metal layer 320 may be equal to or less than a half of a thickness TH2 of the central portion of the dummy intermediate layer 220b contacting (e.g., directly contacting) the upper surface of the second metal layer 320. Likewise, a thickness THY of the outer portion of the opposite electrode 230 contacting (e.g., directly contacting) the lateral surface of the first metal layer 310 may be equal to or less than a half of a thickness T3 of the central portion of the opposite electrode 230. A thickness TH4′ of the outer portion of the dummy opposite electrode 230b overlapping the lateral surface of the second metal layer 320 may be equal to or less than a half of a thickness TH4 of the central portion of the dummy opposite electrode 230b.

Referring to FIG. 3K, a capping layer 400 and an encapsulation layer 500 may be formed on the light-emitting diode ED.

The capping layer 400 may improve an external light-emission efficiency of the light-emitting diode ED based on a constructive interference principle. The capping layer 400 may be an organic capping layer including an organic material, an inorganic capping layer including an inorganic material, or a composite capping layer including an organic material and an inorganic material. The capping layer 400 may be disposed between the opposite electrode 230 and a first inorganic encapsulation layer 510 described below and between the dummy opposite electrode 230b and the first inorganic encapsulation layer 510. For example, like the dummy intermediate layer 220b and the dummy opposite electrode 230b of FIG. 3J described above, a portion of the capping layer 400 disposed on the metal bank layer 300 may extend to overlap the lateral surface of the second metal layer 320. In another example, the capping layer 400 may be omitted.

The encapsulation layer 500 may include at least one inorganic encapsulation layer and at least one organic encapsulation layer. In an embodiment, it is shown in FIG. 3K that the encapsulation layer 500 includes the first inorganic encapsulation layer 510, an organic encapsulation layer 520 on the first inorganic encapsulation layer 510, and a second inorganic encapsulation layer 530 on the organic encapsulation layer 520.

The first inorganic encapsulation layer 510 and the second inorganic encapsulation layer 530 may include at least one inorganic material from among aluminum oxide, titanium oxide, tantalum oxide, hafnium oxide, zinc oxide, silicon oxide, silicon nitride, and silicon oxynitride and be deposited by a chemical vapor deposition. The first and second inorganic encapsulation layers 510 and 530 may include a single layer or a multi-layer including the above materials. The organic encapsulation layer 520 may include a polymer-based material. The polymer-based material may include an acryl-based resin, an epoxy-based resin, polyimide, and polyethylene. In an embodiment, the organic encapsulation layer 520 may include acrylate.

The first inorganic encapsulation layer 510 having a relatively excellent step coverage may cover at least a portion of the inner surface of the opening OP of the metal bank layer 300 having an undercut structure. In an embodiment, the first inorganic encapsulation layer 510 may continuously extend to overlap (or cover) the upper surface and the lateral surface of the dummy opposite electrode 230b, the lateral surface of the dummy intermediate layer 220b, the lateral surface and the bottom surface (or lower surface) of the second metal layer 320, the lateral surface of the first metal layer 310, and the upper surface of the opposite electrode 230.

The organic encapsulation layer 520 may be positioned on the first inorganic encapsulation layer 510 and may fill at least a portion of the opening OP of the metal bank layer 300. The second inorganic encapsulation layer 530 may be disposed on the organic encapsulation layer 520.

In an embodiment shown in FIGS. 3A to 3K, although the metal bank layer 300 includes the first metal layer 310 and the second metal layer 320 on the first metal layer 310, embodiments are not limited thereto. In an embodiment, the metal bank layer 300 may include the first metal layer 310, the second metal layer 320 on the first metal layer 310, and a third metal layer under the first metal layer 310. The third metal layer may include a material which is the same as or different from a material of the first metal layer 310.

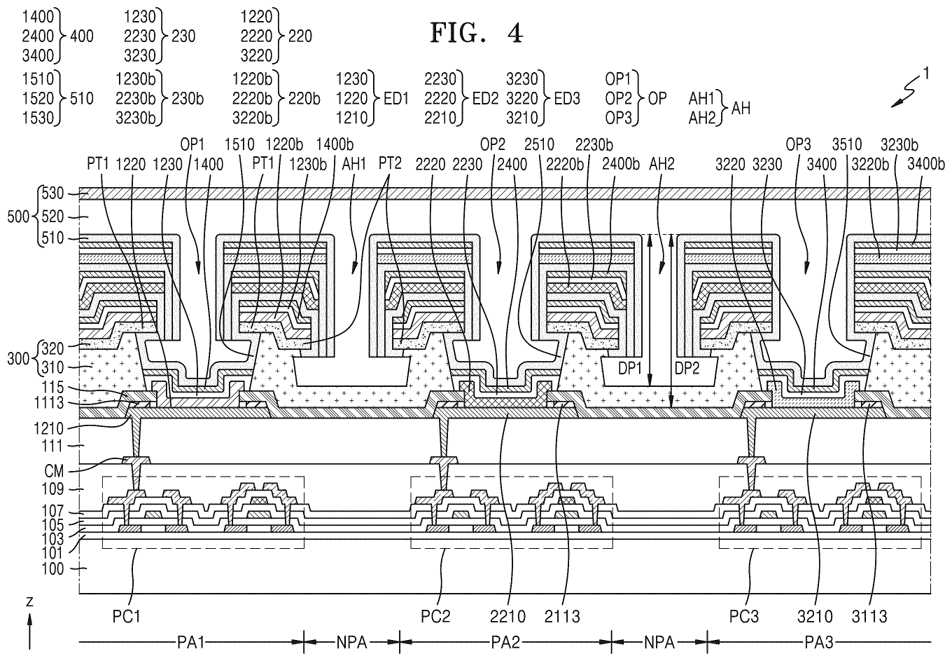

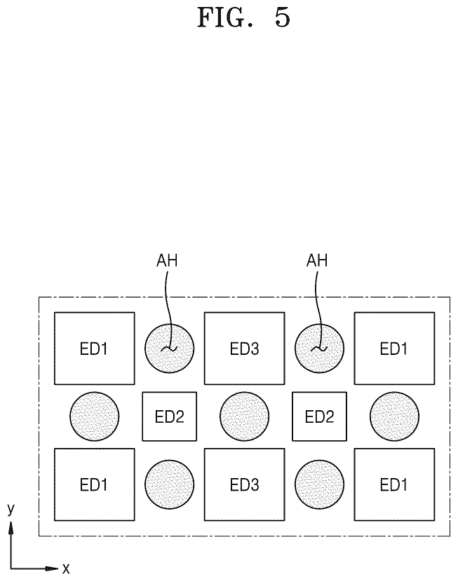

FIG. 4 is a schematic cross-sectional view of the display apparatus 1 according to an embodiment, and FIG. 5 is a schematic plan view of a light-emitting diode and an anchor hole of the display apparatus 1 according to an embodiment.

Referring to FIG. 4, the display apparatus 1 may include first to third sub-pixel areas PA1, PA2, and PA3 and include a non-sub-pixel area NPA between the adjacent sub-pixel areas. The planar shape of the display apparatus 1 may be substantially the same as a planar shape of the substrate 100. Accordingly, in case that the display apparatus 1 includes the first to third sub-pixel areas PA1, PA2, and PA3 and the non-sub-pixel area NPA, it may represent that the substrate 100 includes the first to third sub-pixel areas PA1, PA2, and PA3 and the non-sub-pixel area NPA.

First to third light-emitting diodes ED1, ED2, and ED3 may be disposed over the substrate 100. The first to third light-emitting diodes ED1, ED2, and ED3 may be respectively arranged in the first to third sub-pixel areas PA1, PA2, and PA3. As in FIG. 5, the first light-emitting diode ED1 and the third light-emitting diode ED3 may be alternately arranged in case of forming a first row in a first direction (e.g., the x-axis direction). For example, the second light-emitting diode ED2 may be repeatedly arranged in case of forming a second row parallel to the first row and be arranged between the first light-emitting diode ED1 and the third light-emitting diode ED3 in the first direction.

First to third sub-pixel circuits PC1, PC2, and PC3 may be disposed between the substrate 100 and the first to third light-emitting diodes ED1, ED2, and ED3. The first to third sub-pixel circuits PC1, PC2, and PC3 may each include the transistor and the storage capacitor described above with reference to FIG. 2A or 2B. In an embodiment, it is shown in FIG. 4 that the first to third sub-pixel circuits PC1, PC2, and PC3 each have the same structure as the structure of the sub-pixel circuit PC (see FIG. 3) described with reference to FIG. 3, and a specific structure is the same as that described above.

The first to third light-emitting diodes ED1, ED2, and ED3 respectively electrically connected to the first to third sub-pixel circuits PC1, PC2, and PC3 may each have a stack structure of the sub-pixel electrode, the intermediate layer, and the opposite electrode.

As an example, the first light-emitting diode ED1 may include a first sub-pixel electrode 1210, a first intermediate layer 1220, and a first opposite electrode 1230. The first sub-pixel electrode 1210 may be electrically connected to the first sub-pixel circuit PC1. The second light-emitting diode ED2 may include a second sub-pixel electrode 2210, a second intermediate layer 2220, and a second opposite electrode 2230. The second sub-pixel electrode 2210 may be electrically connected to the second sub-pixel circuit PC2. The third light-emitting diode ED3 may include a third sub-pixel electrode 3210, a third intermediate layer 3220, and a third opposite electrode 3230. The third sub-pixel electrode 3210 may be electrically connected to the third sub-pixel circuit PC3.

The first intermediate layer 1220, the second intermediate layer 2220, and the third intermediate layer 3220 may each include the emission layer, and the first and/or second common layer as described with reference to FIG. 3L. Specific structure and material are the same as those described above. For example, the emission layer of the first intermediate layer 1220, the emission layer of the second intermediate layer 2220, and the emission layer of the third intermediate layer 3220 may emit lights of different colors.

The first sub-pixel electrode 1210, the second sub-pixel electrode 2210, and the third sub-pixel electrode 3210 may each include an inner portion and an outer portion surrounding the inner portion. In the description, an “outer portion (or neighboring portion)” of the sub-pixel electrode denotes a portion of the sub-pixel electrode including the edge portion of the sub-pixel electrode, and an “inner portion of the sub-pixel electrode” denotes another portion of the sub-pixel area surrounded by the outer portion (or neighboring portion).

The first intermediate layer 1220 may overlap and contact the inner portion of the first sub-pixel electrode 1210, and the first opposite electrode 1230 may overlap the first intermediate layer 1220. The insulating layer 115 may be disposed on the outer portion of the first sub-pixel electrode 1210. The insulating layer 115 may overlap the outer portion of the first sub-pixel electrode 1210 and extend on the second organic insulating layer 111 to cover the lateral surface of the first sub-pixel electrode 1210. A first protective layer 1113 may be disposed between the insulating layer 115 and the outer portion of the first sub-pixel electrode 1210. The insulating layer 115 and the first protective layer 1113 each may be positioned on the outer portion of the first sub-pixel electrode 1210, and may not be formed or present on the inner portion of the first sub-pixel electrode 1210. For example, the insulating layer 115 and the first protective layer 1113 may each include an opening overlapping the inner portion of the first sub-pixel electrode 1210.

For example, the second intermediate layer 2220 may overlap and contact the inner portion of the second sub-pixel electrode 2210, and the second opposite electrode 2230 may overlap the second intermediate layer 2220. The outer portion of the second sub-pixel electrode 2210 may overlap the insulating layer 115. The third intermediate layer 3220 may overlap and contact the inner portion of the third sub-pixel electrode 3210, and the third opposite electrode 3230 may overlap the third intermediate layer 3220. The outer portion of the third sub-pixel electrode 3210 may overlap the insulating layer 115. The insulating layer 115 may overlap the outer portion of each of the second sub-pixel electrode 2210 and the third sub-pixel electrode 3210 and extend on the second organic insulating layer 111 to cover the lateral surface of each of the second sub-pixel electrode 2210 and the third sub-pixel electrode 3210. A second protective layer 2113 may be disposed between the insulating layer 115 and the second sub-pixel electrode 2210, and a third protective layer 3113 may be disposed between the insulating layer 115 and the third sub-pixel electrode 3210.

The metal bank layer 300 may include first to third openings OP1, OP2, and OP3 respectively overlapping the third to third sub-pixel electrodes 1210, 2210, and 3210. The first to third openings OP1, OP2, and OP3 of the metal bank layer 300 of FIG. 4 may each have the same structure as the opening OP (see FIG. 3F) described above with reference to FIG. 3F.

As an example, the first to third openings OP1, OP2, and OP3 may each pass through the bottom surface (or lower surface) from the upper surface of the metal bank layer 300 and have a cross-sectional structure of an undercut shape. The lateral surface of the first metal layer 310 facing a relevant opening among the first to third openings OP1, OP2, and OP3 of the metal bank layer 300 may have a forward tapered shape and have a slope angle equal to or greater than 600 and less than 90°. The second metal layer 320 of the metal bank layer 300 may include the first tip PT1 extending to a relevant opening among the first to third openings OP1, OP2, and OP3. The length of the first tip PT1 may be 2 μm or less. In an embodiment, the length of the first tip PT1 may be about 0.3 μm to about 1 μm, or about 0.3 μm to about 0.7 μm.

In the display apparatus 1 according to an embodiment, the first to third intermediate layer 1220, 2220, and 3220 and the first to third opposite electrodes 1230, 2230, and 3230 may be deposited due to the structure of the metal bank layer 300 including the first to third openings OP1, OP2, and OP3 having the undercut structure without using a separate mask in case of forming the first to third intermediate layer 1220, 2220, and 3220 and the first to third opposite electrodes 1230, 2230, and 3230. Accordingly, damage to the display apparatus 1 due to the mask may be prevented and resolution may be improved.

The first opposite electrode 1230 disposed in the first opening OP1 of the metal bank layer 300, the second opposite electrode 2230 disposed in the second opening OP2 of the metal bank layer 300, and the third opposite electrode 3230 disposed in the third opening OP3 of the metal bank layer 300 may be spatially separated from each other. The first opposite electrode 1230, the second opposite electrode 2230, and the third opposite electrode 3230 may be connected (e.g., electrically connected) to each other and may have the same voltage level. As an example, the first opposite electrode 1230, the second opposite electrode 2230, and the third opposite electrode 3230 may each have the same voltage level as a voltage (e.g., a common voltage) provided by the auxiliary line VSL (see FIG. 2A).

The first to third opposite electrodes 1230, 2230, and 3230 may each be connected (e.g., electrically connected) to the auxiliary line VSL (see FIG. 2A) through the metal bank layer 300. As an example, the outer portion of the first opposite electrode 1230 may be electrically connected to (e.g., directly contact) the lateral surface of the metal bank layer 300 (e.g., the lateral surface of the first metal layer 310) facing the first opening OP1, the metal bank layer 300 may be connected (e.g., electrically connected) to the auxiliary line VSL (see FIG. 2A), and the first opposite electrode 1230 may be connected (e.g., electrically connected) to the auxiliary line VSL (see FIG. 2A). The outer portion of the second opposite electrode 2230 may be electrically connected to (e.g., directly contact) the lateral surface of the metal bank layer 300 (e.g., the lateral surface of the first metal layer 310) facing the second opening OP2, the metal bank layer 300 may be connected (e.g., electrically connected) to the auxiliary line VSL (see FIG. 2A), and the second opposite electrode 2230 may be connected (e.g., electrically connected) to the auxiliary line VSL (see FIG. 2A). The outer portion of the third opposite electrode 3230 may be connected (e.g., electrically connected) to (e.g., directly contact) the lateral surface of the metal bank layer 300 (e.g., the lateral surface of the first metal layer 310) facing the third opening OP3, the metal bank layer 300 may be connected (e.g., electrically connected) to the auxiliary line VSL (see FIG. 2A), and the third opposite electrode 3230 may be connected (e.g., electrically connected) to the auxiliary line VSL (see FIG. 2A).

As a material forming the intermediate layer and a material forming the opposite electrode are deposited without using a mask, the material forming the intermediate layer and the material forming the opposite electrode may be deposited in a relevant opening among the first to third openings OP1, OP2, and OP3, and deposited on the metal bank layer 300. At least one dummy intermediate layer 220b and at least one dummy opposite electrode 230b may be disposed on the metal bank layer 300. The at least one dummy intermediate layer 220b may be separated and spaced apart from the first to third intermediate layers 1220, 2220, and 3220 respectively positioned in the first to third openings OP1, OP2, and OP3. The at least one dummy opposite electrode 230b may be separated and spaced apart from the first to third opposite electrodes 1230, 2230, and 3230 respectively positioned in the first to third openings OP1, OP2, and OP3.

As shown in FIG. 4, the dummy intermediate layer 220b may include a first dummy intermediate layer 1220b arranged in the first sub-pixel area PA1, a second dummy intermediate layer 2220b arranged in the second sub-pixel area PA2, and a third dummy intermediate layer 3220b arranged in the third sub-pixel area PA3. The dummy opposite electrode 230b may include a first dummy opposite electrode 1230b arranged in the first sub-pixel area PA1, a second dummy opposite electrode 2230b arranged in the second sub-pixel area PA2, and a third dummy opposite electrode 3230b arranged in the third sub-pixel area PA3. For example, on the second metal layer 320, the first dummy intermediate layer 1220b, the first dummy opposite electrode 1230b, the second dummy intermediate layer 2220b, the second dummy opposite electrode 2230b, the third dummy intermediate layer 3220b, and the third dummy opposite electrode 3230b may be sequentially stacked. For example, the first dummy intermediate layer 1220b, the first dummy opposite electrode 1230b, the second dummy intermediate layer 2220b, the second dummy opposite electrode 2230b, the third dummy intermediate layer 3220b, and the third dummy opposite electrode 3230b may be arranged to overlap each other.

As the dummy intermediate layer 220b is separated from the intermediate layer 220 by an undercut structure of the metal bank layer 300, the dummy intermediate layer 220b and the intermediate layer 220 may include the same material in each sub-pixel area. For example, the first dummy intermediate layer 1220b and the first intermediate layer 1220 may include the same material. The second dummy intermediate layer 2220b and the second intermediate layer 2220 may include the same material. The third dummy intermediate layer 3220b and the third intermediate layer 3220 may include the same material. However, as the first intermediate layer 1220, the second intermediate layer 2220, and the third intermediate layer 3220 respectively include different materials to emit light of different colors, the first dummy intermediate layer 1220b, the second dummy intermediate layer 2220b, and the third dummy intermediate layer 3220b may respectively include different materials.

As the dummy opposite electrode 230b is separated from the opposite electrode 230 by an undercut structure of the metal bank layer 300, the dummy opposite electrode 230b and the opposite electrode 230 may include the same material in each sub-pixel area. For example, the first dummy opposite electrode 1230b and the first opposite electrode 1230 may include the same material. The second dummy opposite electrode 2230b and the second opposite electrode 2230 may include the same material. The third dummy opposite electrode 3230b and the third opposite electrode 3230 may include the same material. However, as the first opposite electrode 1230, the second opposite electrode 2230, and the third opposite electrode 3230 include the same material, the first dummy opposite electrode 1230b, the second dummy opposite electrode 2230b, and the third dummy opposite electrode 3230b may include the same material. For example, the first opposite electrode 1230, the first dummy opposite electrode 1230b, the second opposite electrode 2230, the second dummy opposite electrode 2230b, the third opposite electrode 3230, and the third dummy opposite electrode 3230b may include the same material.

The capping layer 400 may be disposed on the opposite electrode 230 and the dummy opposite electrode 230b. The capping layer 400 may improve an external light-emission efficiency of the first to third light-emitting diodes ED1, ED2, and ED3. The capping layer 400 may include a first capping layer 1400 disposed on the first opposite electrode 1230 and the first dummy opposite electrode 1230b, a second capping layer 2400 disposed on the second opposite electrode 2230 and the second dummy opposite electrode 2230b, and a third capping layer 3400 disposed on the third opposite electrode 3230 and the third dummy opposite electrode 3230b. For example, the first capping layer 1400 may be arranged in a region between the first opposite electrode 1230 and a first sub-pixel inorganic encapsulation layer 1510 described below, and a region between the first dummy opposite electrode 1230b and the first sub-pixel inorganic encapsulation layer 1510. The second capping layer 2400 may be arranged in a region between the second opposite electrode 2230 and a second sub-pixel inorganic encapsulation layer 2510 described below, and a region between the second dummy opposite electrode 2230b and the second sub-pixel inorganic encapsulation layer 2510. The third capping layer 3400 may be arranged in a region between the third opposite electrode 3230 and a third sub-pixel inorganic encapsulation layer 3510 described below, and a region between the third dummy opposite electrode 3230b and the third sub-pixel inorganic encapsulation layer 3510. A material of the capping layer 400 is the same as that described above with reference to FIG. 3K.

The metal bank layer 300 may include anchor holes AH arranged in the non-sub-pixel area NPA. As an example, the metal bank layer 300 may include a first anchor hole AH1 and a second anchor hole AH2. The first anchor hole AH1 may be arranged between the first opening OP1 and the second opening OP2, and the second anchor hole AH2 may be arranged between the second opening OP2 and the third opening OP3. However, embodiments are not limited thereto. As shown in FIG. 5, the anchor hole AH may be arranged in any portion in the non-sub-pixel area NPA in which the first light-emitting diode ED1, the second light-emitting diode ED2, and the third light-emitting diode ED3 are not arranged. For example, the anchor hole AH may be arranged between the first light-emitting diode ED1 and the third light-emitting diode ED3 forming the first row in the first direction (e.g., the x-axis direction), and arranged between the adjacent second light-emitting diodes ED2 forming the second row parallel to the first row in the first direction. For example, the anchor hole AH may have a circular shape in a plan view as shown in FIG. 5. However, embodiments are not limited thereto and the anchor hole AH may have a polygonal shape.

Like the first to third openings OP1, OP2, and OP3, the anchor holes AH may each have a cross-section of an undercut structure. As an example, the lateral surface of the first metal layer 310 facing a relevant opening of the first anchor hole AH1 and the second anchor hole AH2 of the metal bank layer 300 may have a forward tapered shape and have a slope angle equal to or greater than 60° and less than 90°. The second metal layer 320 of the metal bank layer 300 may include a second tip PT2 extending to a relevant opening of the first anchor hole AH1 and the second anchor hole AH2. For example, a portion of the second metal layer 320 of the metal bank layer 300 may include the second tip PT2 extending to a relevant opening of the first anchor hole AH1 and the second anchor hole AH2 from a point (or portion) at which the bottom surface (or lower surface) of the second metal layer 320 contacts the lateral surface of the first metal layer 310. The length of the second tip PT2 may be 2 μm or less. In an embodiment, the length of the second tip PT2 may be about 0.3 μm to about 1 μm, or about 0.3 μm to about 0.7 μm.

For example, each of the anchor holes AH may be a concave portion formed in case that a portion of the metal bank layer 300 is removed in the thickness direction. For example, the anchor hole AH may be formed by passing through the second metal layer 320 and the removing a portion of the first metal layer 310 in the thickness direction. As an example, the anchor hole AH may have a blind-hole shape that does not completely pass through the metal bank layer 300.

It may be considered that a depth DP1 of the anchor hole AH is a sum of a height in the thickness direction of the concave hole formed in case that a portion of the metal bank layer 300 is removed, and a height of a dummy material disposed on the metal bank layer 300. For example, it may be considered that the depth DP1 of the anchor hole AH is a sum of heights in the thickness direction of the concave hole portion of the metal bank layer 300, the dummy intermediate layers 1220b, 2220b, and 3220b, the dummy opposite electrodes 1230b, 2230b, and 3230b, the dummy capping layers 1400b, 2400b, and 3400b, and the first to third sub-pixel inorganic encapsulation layers 1510, 2510, and 3510. The depth DP1 of the anchor hole AH may be less than a sum DP2 of the heights of the metal bank layer 300 and the dummy material disposed on the metal bank layer 300.

The anchor hole AH may expose the upper surface of the first metal layer 310 that is partially removed, to the outside. Accordingly, in the case where the organic encapsulation layer 520 described below fills the openings OP and the anchor holes AH, the upper surface of the first metal layer 310 may contact (e.g., directly contact) the organic encapsulation layer 520 through the anchor hole AH.

The anchor holes AH may prevent a defect such as layer floating. In a method of depositing the intermediate layer 220 and the opposite electrode 230 in the opening OP by using the metal bank layer 300 according to a comparative example, as there is no anchor hole AH, the dummy intermediate layer 220b, the dummy opposite electrode 230b, and the first inorganic encapsulation layer 510 may be successively disposed on the second metal layer 320. For example, during a process of etching the dummy intermediate layer 220b and the dummy opposite electrode 230b, there is a risk of defects such as layer floating due to moisture transmission occur. As in FIG. 4, in the case where the anchor holes AH are additionally arranged in the non-sub-pixel area NPA, the undercut structure of the anchor hole AH may disconnect the dummy intermediate layer 220b and the dummy opposite electrode 230b, and thus, prevent a growth of defects such as layer floating. Furthermore, as the undercut structure of the anchor hole AH forms an unevenness in the thickness direction, the anchor hole AH may hold a cover layer such as the first inorganic encapsulation layer 510 described below, and thus, prevent a defect of layer floating itself.

The first to third light-emitting diodes ED1, ED2, and ED3 may be encapsulated by the encapsulation layer 500. In an embodiment, it is shown in FIG. 4 that the encapsulation layer 500 includes the first inorganic encapsulation layer 510, the organic encapsulation layer 520 on the first inorganic encapsulation layer 510, and the second inorganic encapsulation layer 530 on the organic encapsulation layer 520. The materials of the first inorganic encapsulation layer 510, the organic encapsulation layer 520, and the second inorganic encapsulation layer 530 are the same as the materials described above with reference to FIG. 3K.

The first inorganic encapsulation layer 510 may cover a structure and/or a layer under the first inorganic encapsulation layer 510. As an example, the first inorganic encapsulation layer 510 having a relatively excellent step coverage may cover an inner structure and/or a layer of each of the openings OP and the anchor holes AH. The first inorganic encapsulation layer 510 may include the first sub-pixel inorganic encapsulation layer 1510 covering the inner surface of the first opening OP1, the second sub-pixel inorganic encapsulation layer 2510 covering the inner surface of the second opening OP2, and the third sub-pixel inorganic encapsulation layer 3510 covering the inner surface of the third opening OP3. For example, the first sub-pixel inorganic encapsulation layer 1510 may overlap the lateral surface and the bottom surface (or lower surface) of the second metal layer 320 facing the first opening OP1, the lateral surface of the first metal layer 310 facing the first opening OP1, and the upper surface of the first opposite electrode 1230. The second sub-pixel inorganic encapsulation layer 2510 may overlap the lateral surface and the bottom surface (or lower surface) of the second metal layer 320 facing the second opening OP2, the lateral surface of the first metal layer 310 facing the second opening OP2, and the upper surface of the second opposite electrode 2230. The third sub-pixel inorganic encapsulation layer 3510 may overlap the lateral surface and the bottom surface (or lower surface) of the second metal layer 320 facing the third opening OP3, the lateral surface of the first metal layer 310 facing the third opening OP3, and the upper surface of the third opposite electrode 3230.

The first inorganic encapsulation layer 510 may cover not only the inner surface of each of the first opening OP1, the second opening OP2, and the third opening OP3, but also surround (e.g., entirely surround) the dummy intermediate layer 220b and the dummy opposite electrode 230b. As an example, the first sub-pixel inorganic encapsulation layer 1510 may be continuously arranged to surround the upper surface and two opposite lateral surfaces of the first capping layer 1400, two opposite lateral surfaces of the first dummy opposite electrode 1230b, and two opposite lateral surfaces of the first dummy intermediate layer 1220b. The second sub-pixel inorganic encapsulation layer 2510 may be continuously arranged to surround the upper surface and two opposite lateral surfaces of the second capping layer 2400, two opposite lateral surfaces of the second dummy opposite electrode 2230b, and two opposite lateral surfaces of the second dummy intermediate layer 2220b. The third sub-pixel inorganic encapsulation layer 3510 may be continuously arranged to surround the upper surface and two opposite lateral surfaces of the third capping layer 3400, two opposite lateral surfaces of the third dummy opposite electrode 3230b, and two opposite lateral surfaces of the third dummy intermediate layer 3220b. For example, the first sub-pixel inorganic encapsulation layer 1510 may be arranged to overlap the inner surface of the first opening OP1, the upper surface and two opposite lateral surfaces of the first dummy opposite electrode 1230b, and two opposite lateral surfaces of the first dummy intermediate layer 1220b. The second sub-pixel inorganic encapsulation layer 2510 may be arranged to overlap the inner surface of the second opening OP2, the upper surface and two opposite lateral surfaces of the second dummy opposite electrode 2230b, two opposite lateral surfaces of the first dummy opposite electrode 1230b, and two opposite lateral surfaces of the first dummy intermediate layer 1220b. The third sub-pixel inorganic encapsulation layer 3510 may be arranged to overlap the inner surface of the third opening OP3, the upper surface and two opposite lateral surfaces of the third dummy opposite electrode 3230b, two opposite lateral surfaces of the second dummy opposite electrode 2230b, two opposite lateral surfaces of the second dummy intermediate layer 2220b, two opposite lateral surfaces of the first dummy opposite electrode 1230b, and two opposite lateral surfaces of the first dummy intermediate layer 1220b.

For example, the end portion of the first inorganic encapsulation layer 510 may contact (e.g., directly contact) the lateral surface of the metal bank layer 300 facing the anchor hole AH. As an example, the first sub-pixel inorganic encapsulation layer 1510 may cover the first dummy intermediate layer 1220b and the first dummy opposite electrode 1230b disposed on the second metal layer 320, and the end portion of the first sub-pixel inorganic encapsulation layer 1510 may contact (e.g., directly contact) the lateral surface of the first metal layer 310 facing the anchor hole AH.

Through the structure of the first inorganic encapsulation layer 510, the defect of the light-emitting diode ED due to moisture transmission may be prevented. As described above, in a method of depositing the intermediate layer 220 and the opposite electrode 230 in the opening OP by using the metal bank layer 300 according to a comparative example, as there is no anchor hole AH, the dummy intermediate layer 220b, the dummy opposite electrode 230b, and the first inorganic encapsulation layer 510 may be successively disposed on the second metal layer 320. In case of etching the dummy intermediate layer 220b and the dummy opposite electrode 230b is performed, the first inorganic encapsulation layer 510 may be etched together, and the lateral surfaces of the dummy intermediate layer 220b and the dummy opposite electrode 230b facing the non-sub-pixel area NPA may be exposed. For example, as the first inorganic encapsulation layer 510 does not completely cover the dummy intermediate layer 220b and the dummy opposite electrode 230b, moisture transmission may occur to the dummy intermediate layer 220b and the dummy opposite electrode 230b. For example, during a process of stripping a photoresist used to etch the dummy intermediate layer 220b and the dummy opposite electrode 230b, there is a risk that a layer floating defect due to moisture transmission of the dummy intermediate layer 220b and the dummy opposite electrode 230b occurs. As shown in FIG. 4, in the case where the first inorganic encapsulation layer 510 completely covers the dummy intermediate layer 220b and the dummy opposite electrode 230b disposed on the metal bank layer 300, a moisture transmission path of the dummy intermediate layer 220b and the dummy opposite electrode 230b disappears. For example, in the display apparatus according to an embodiment, as the first inorganic encapsulation layer 510 may cover even the lateral surfaces of the dummy intermediate layer 220b and the dummy opposite electrode 230b facing the anchor hole AH, there is an effect of preventing defects such as layer floating due to moisture transmission and the like.

The organic encapsulation layer 520 may be disposed on the first inorganic encapsulation layer 510. The organic encapsulation layer 520 may fill at least a portion of each of the openings OP and the anchor holes AH. For example, as the organic encapsulation layer 520 includes a polymer-based organic material, the organic encapsulation layer 520 may fill the insides of the first to third openings OP1, OP2, and OP3, the first anchor hole AH1 and the second anchor hole AH2. For example, the organic encapsulation layer 520 may respectively and contact (e.g., directly contact) the first sub-pixel inorganic encapsulation layer 1510, the second sub-pixel inorganic encapsulation layer 2510, and the third sub-pixel inorganic encapsulation layer 3510 through the first to third openings OP1, OP2, and OP3. The organic encapsulation layer 520 may contact (e.g., directly contact) the upper surface of the first metal layer 310 that is partially removed through the first anchor hole AH1 and the second anchor hole AH2. The organic encapsulation layer 520 may planarize a step difference due to the openings OP and the anchor holes AH. The second inorganic encapsulation layer 530 may be disposed on the organic encapsulation layer 520.

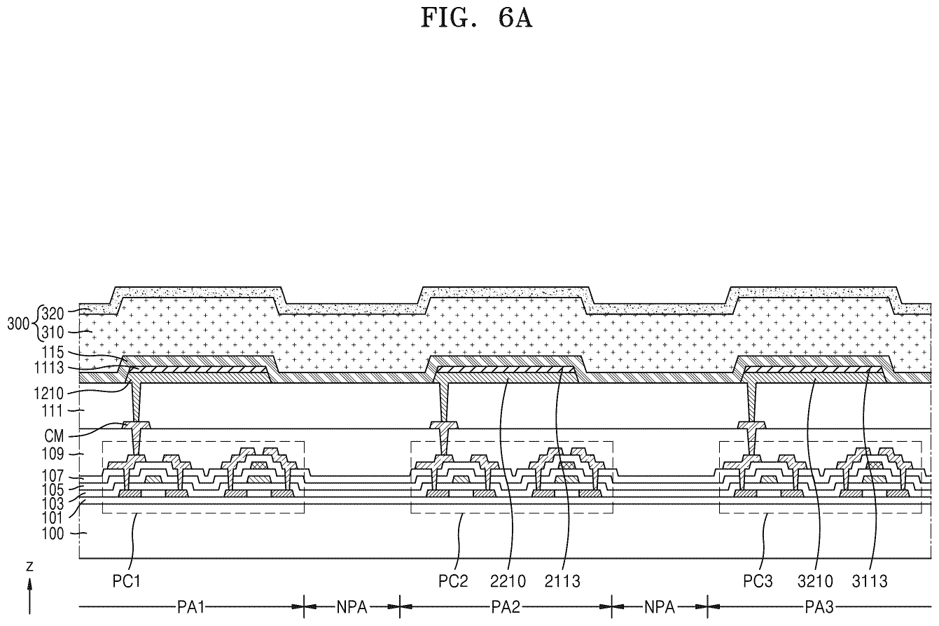

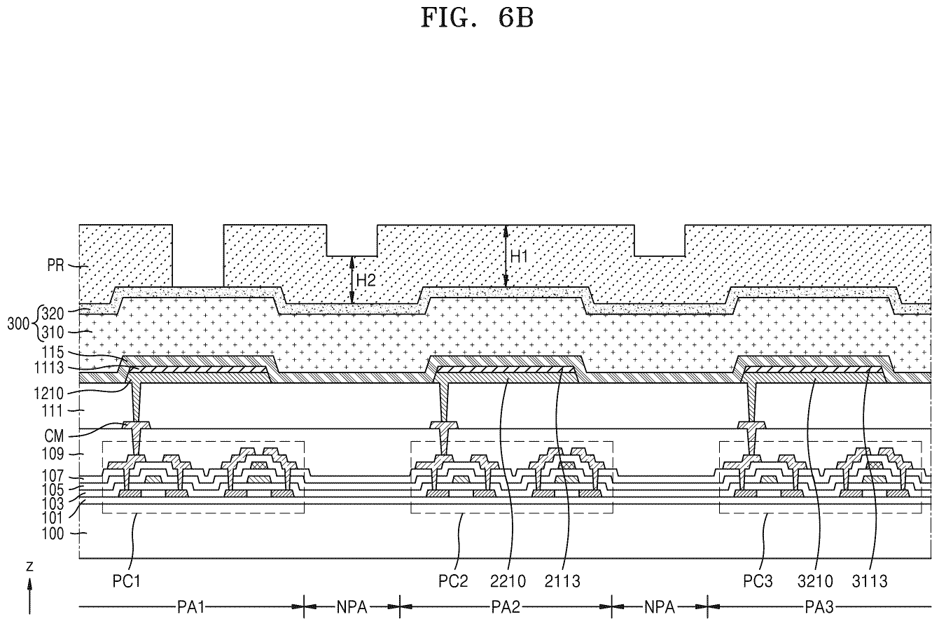

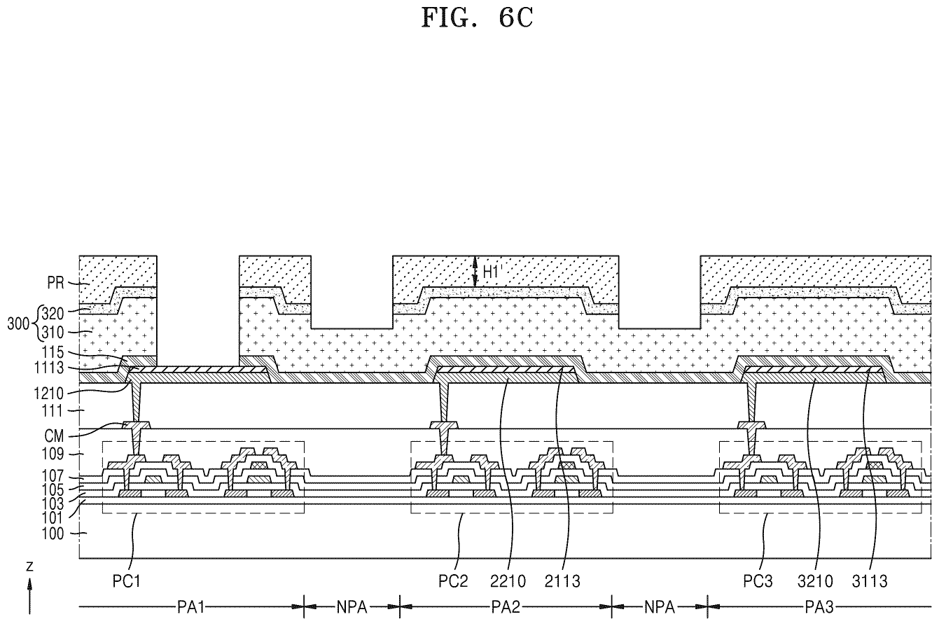

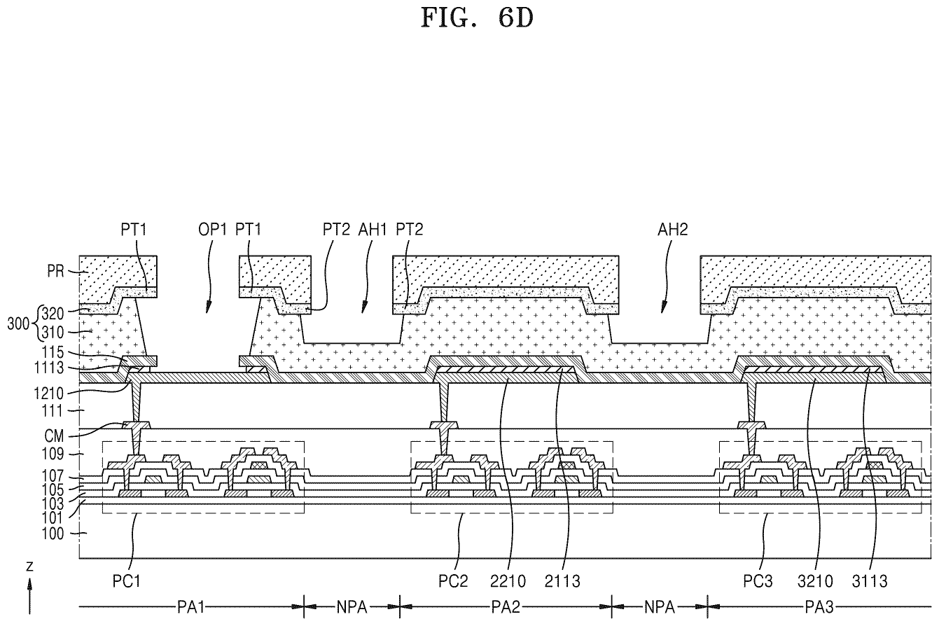

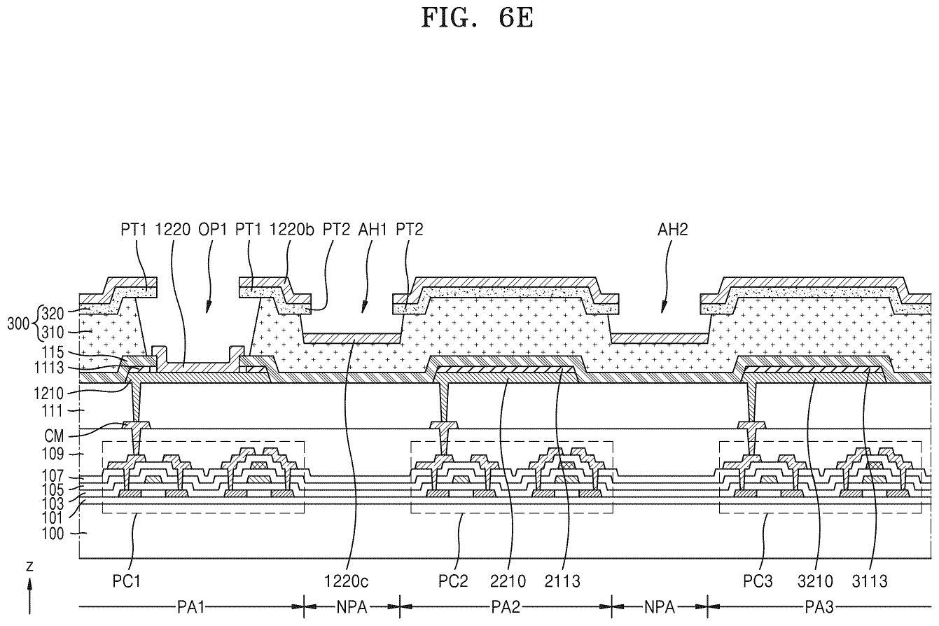

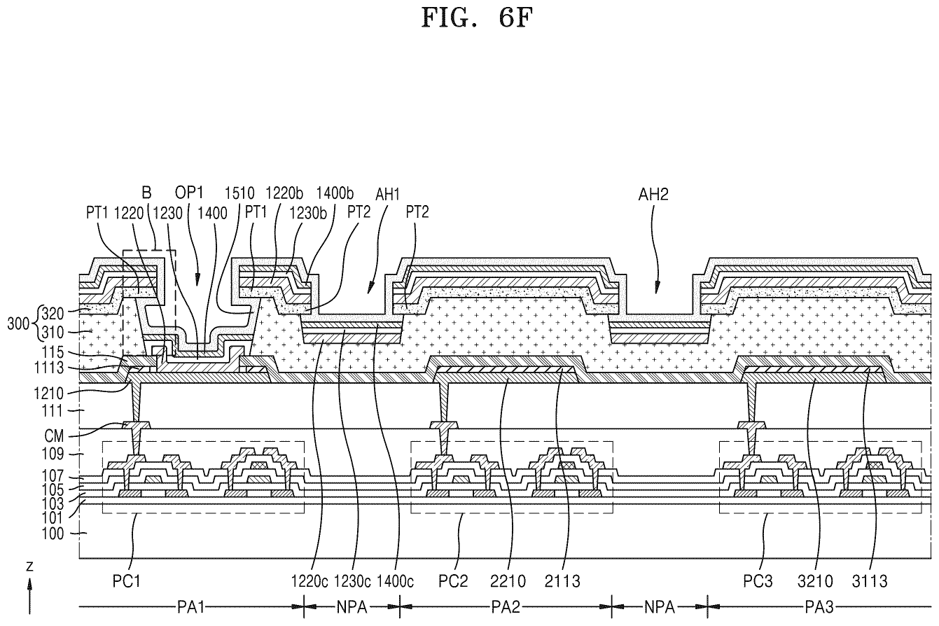

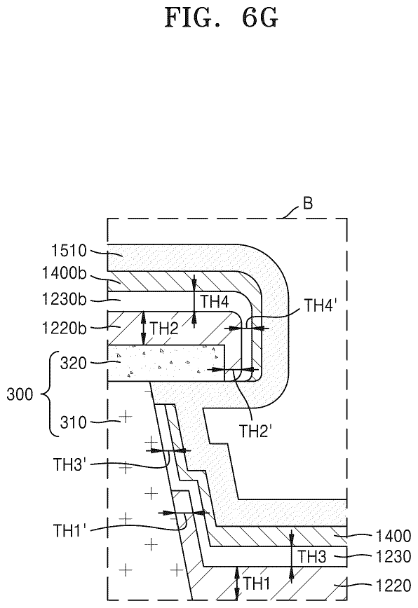

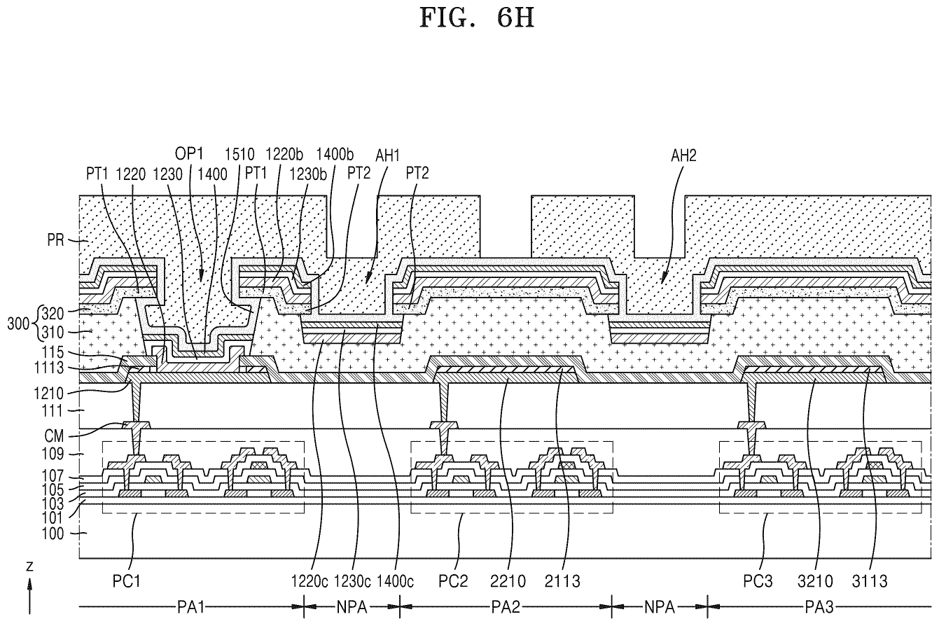

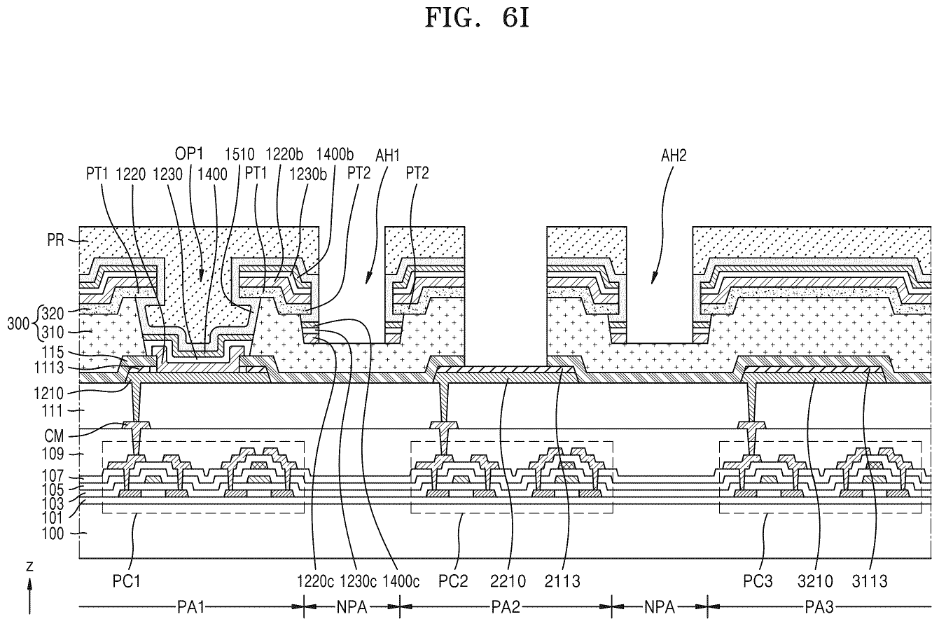

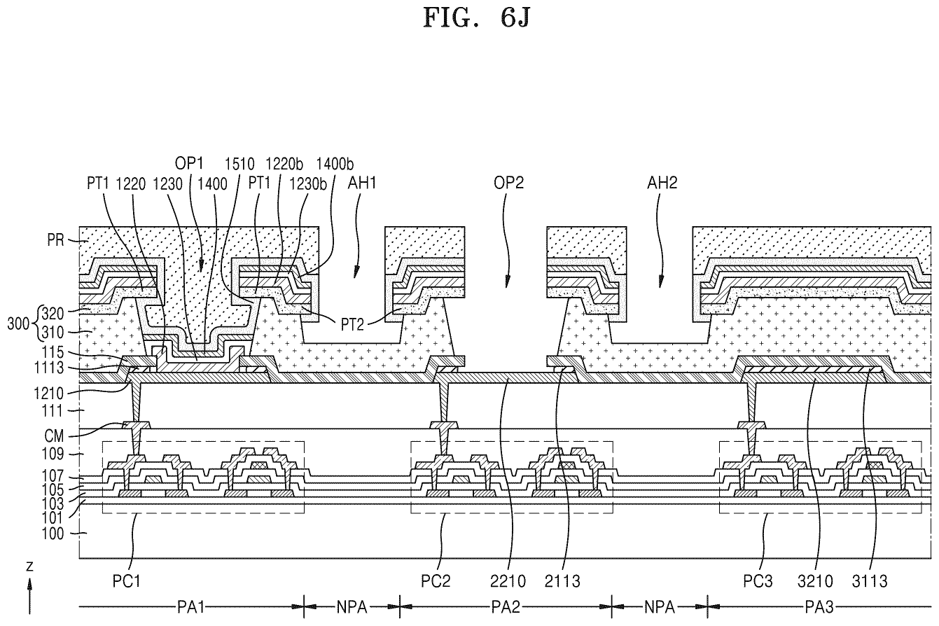

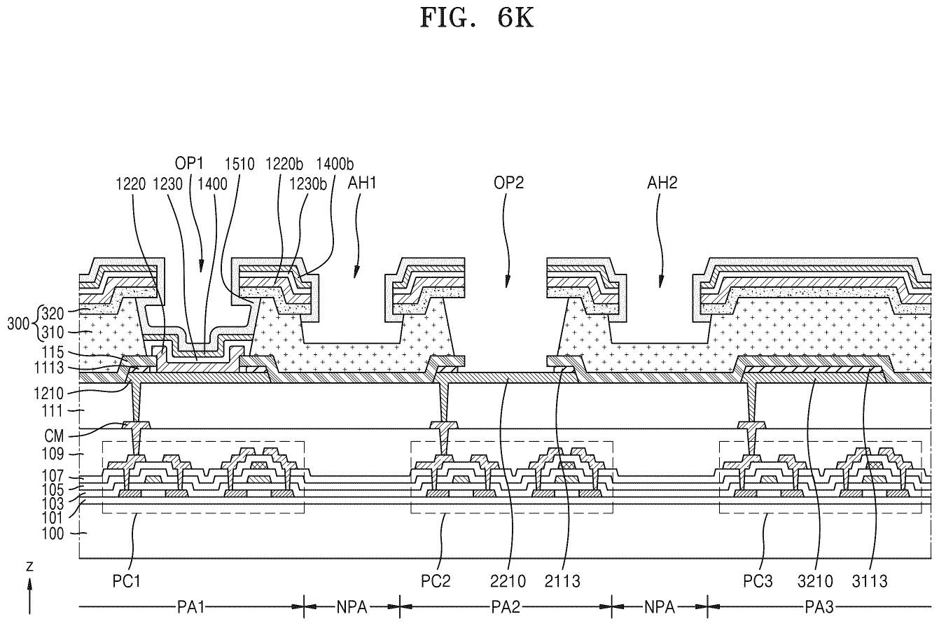

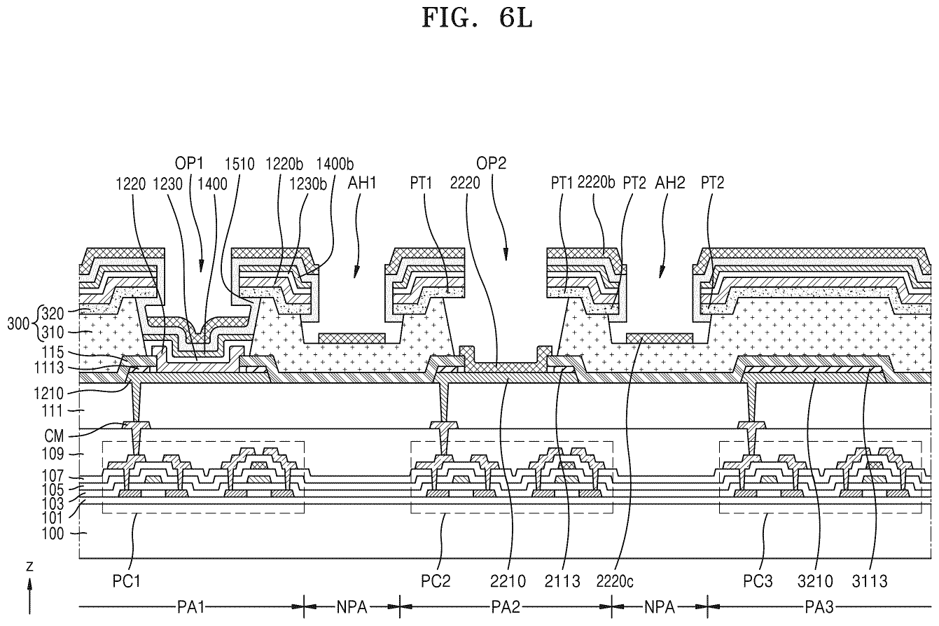

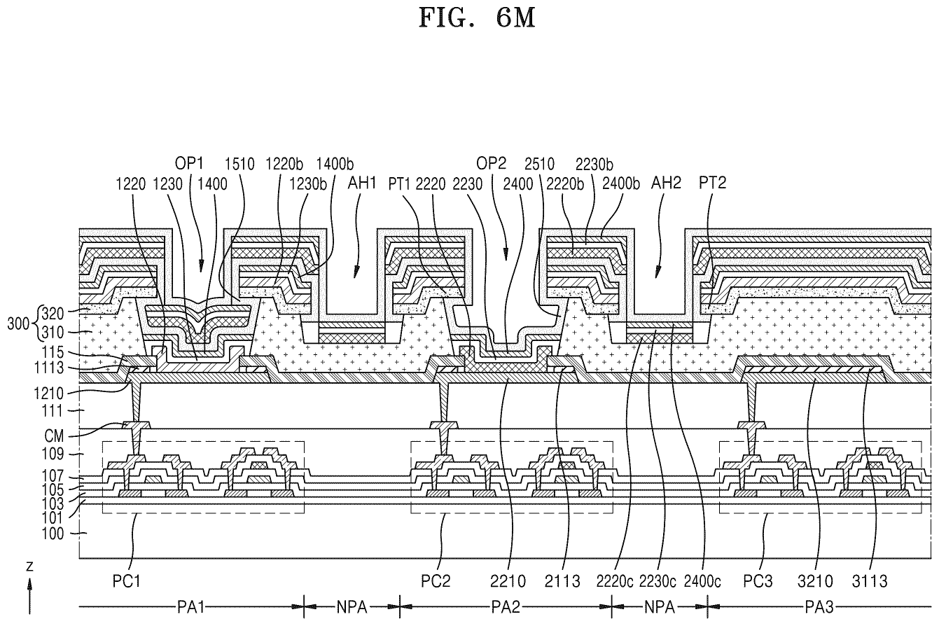

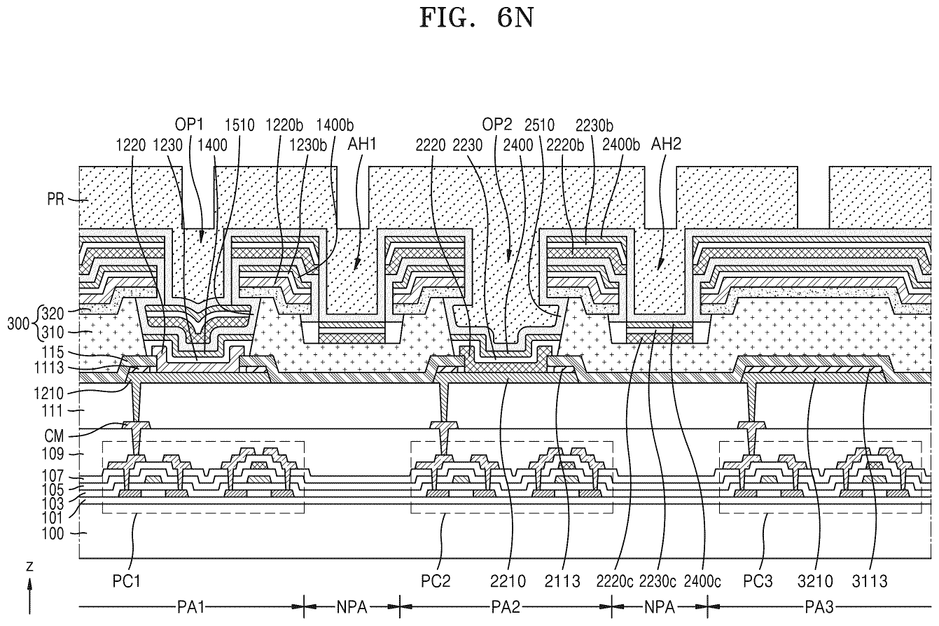

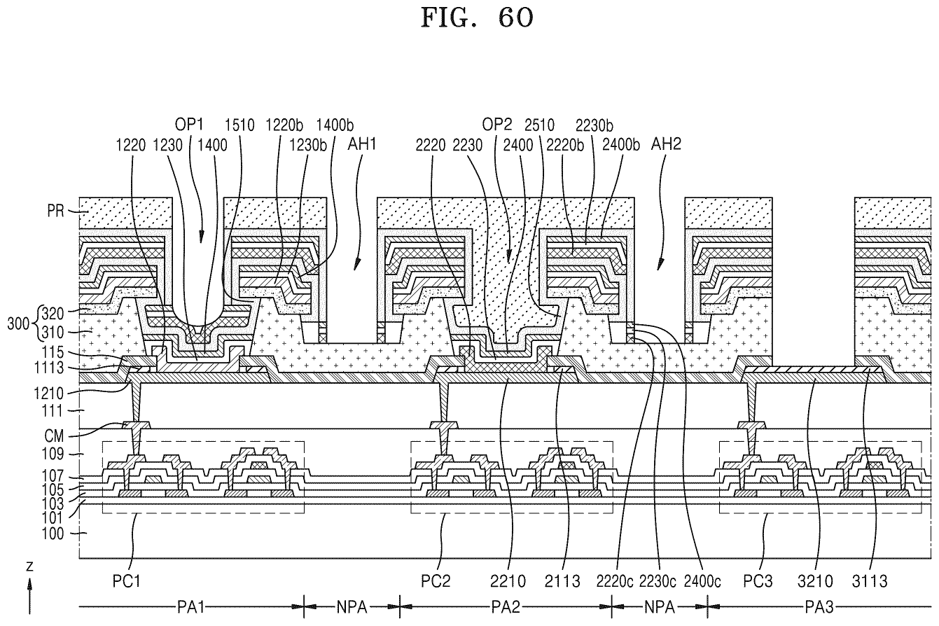

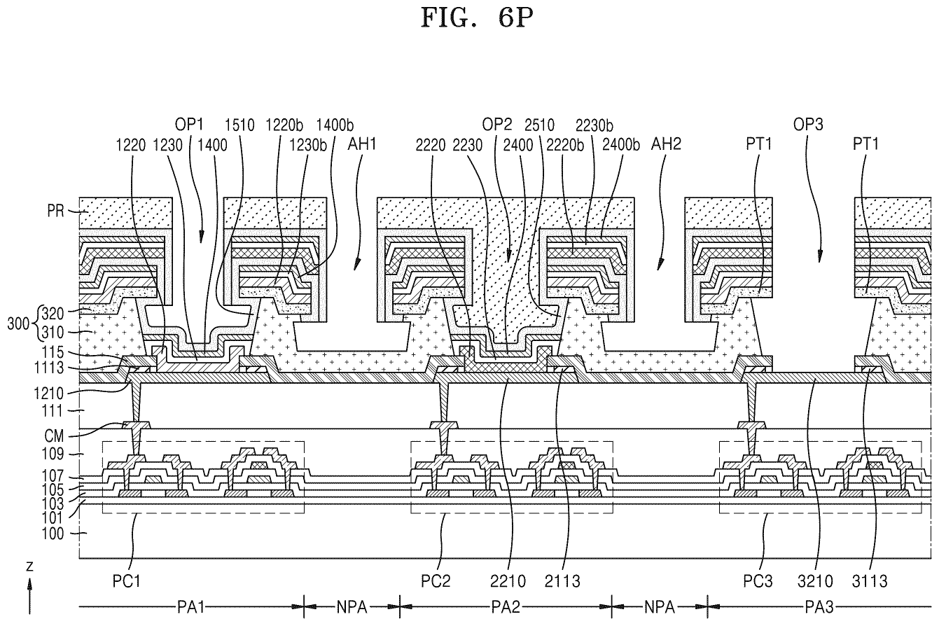

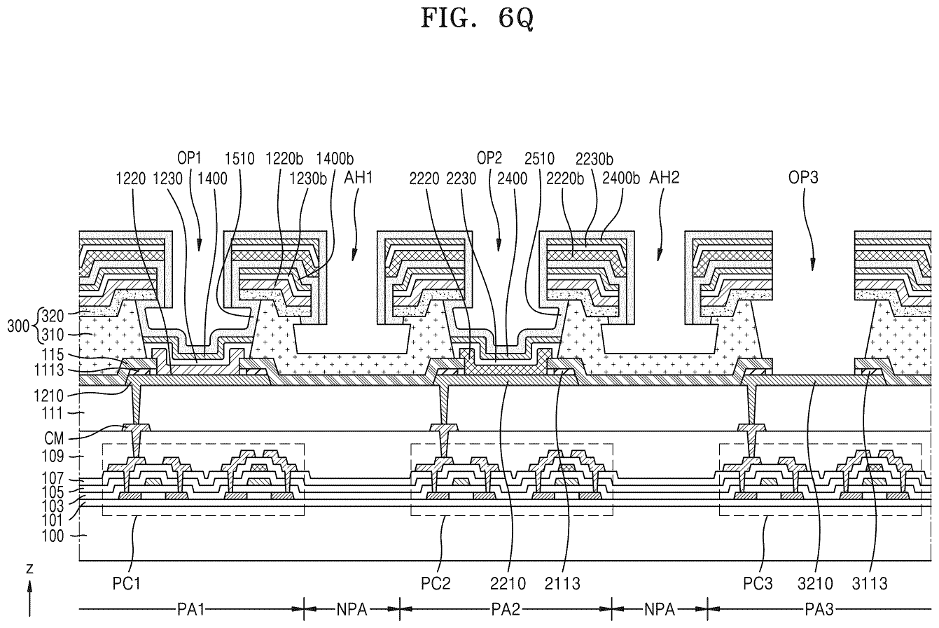

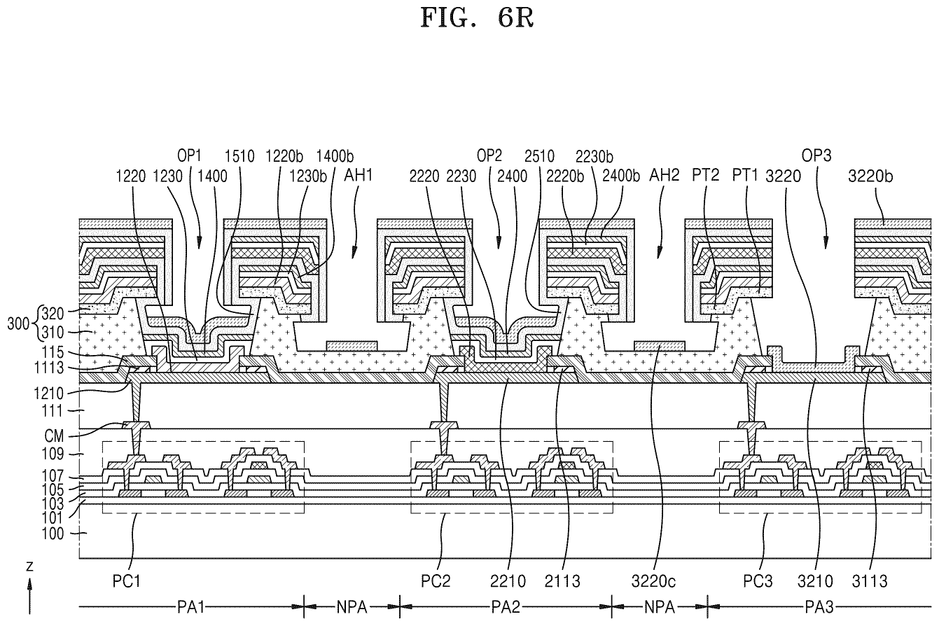

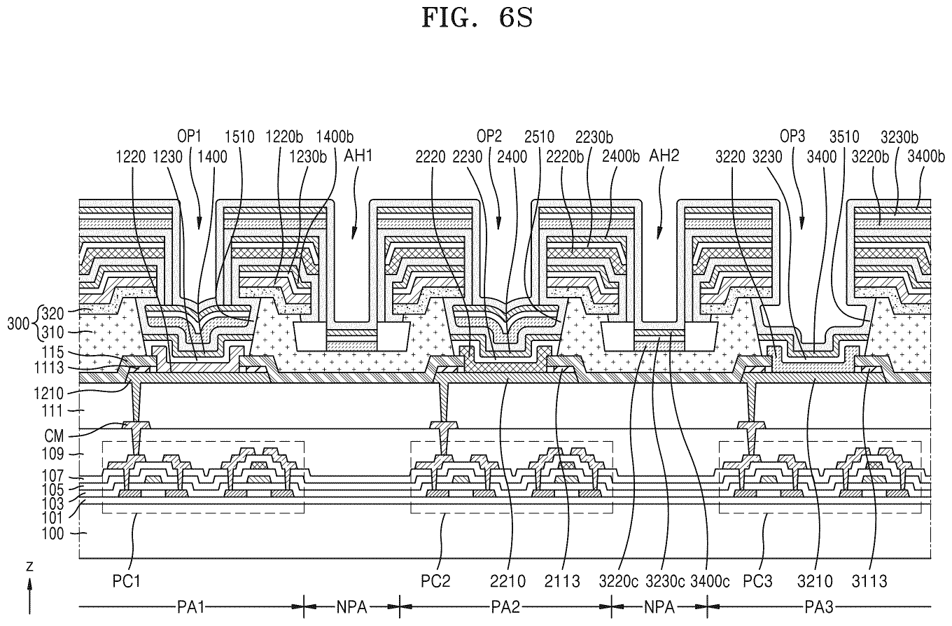

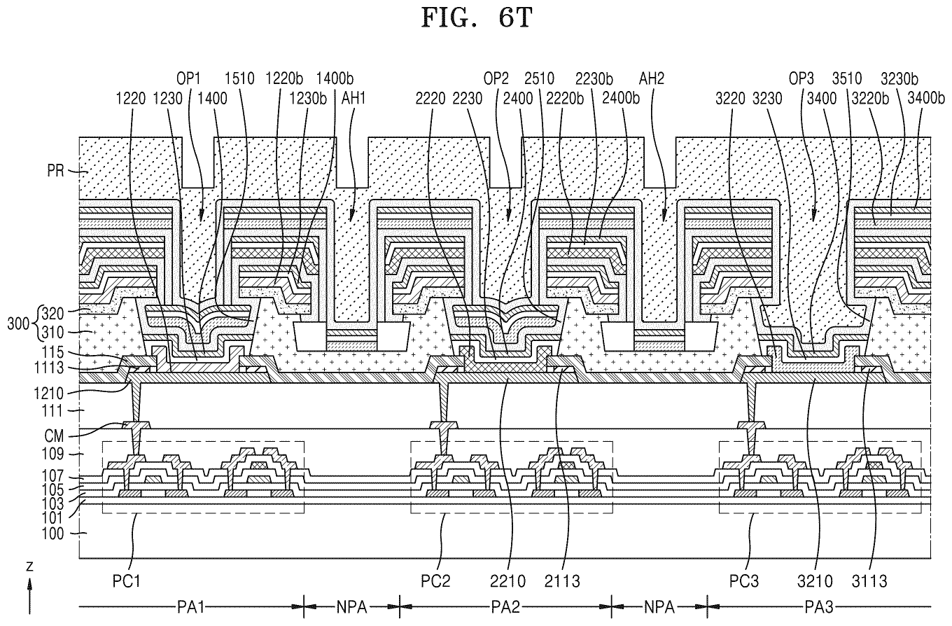

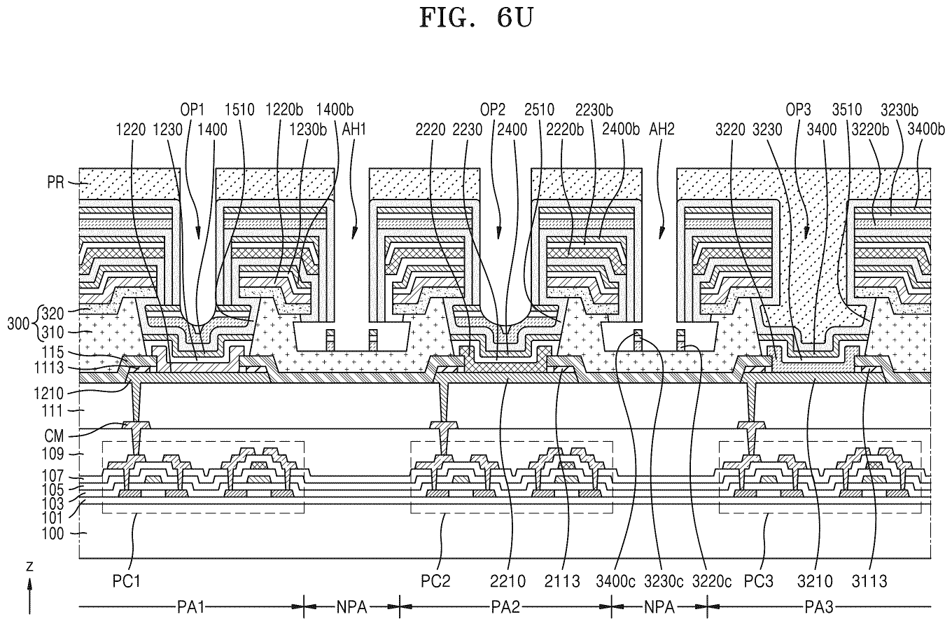

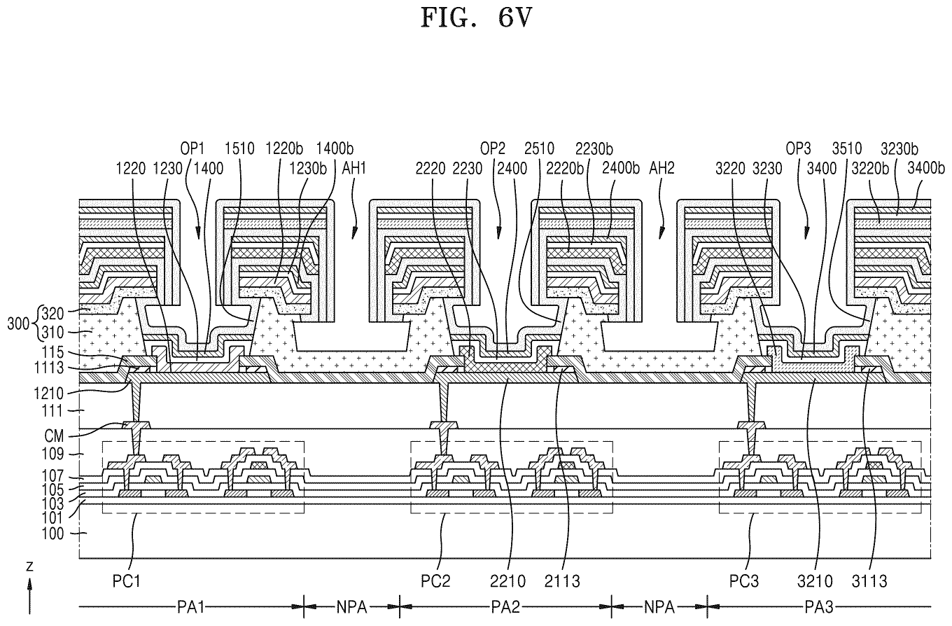

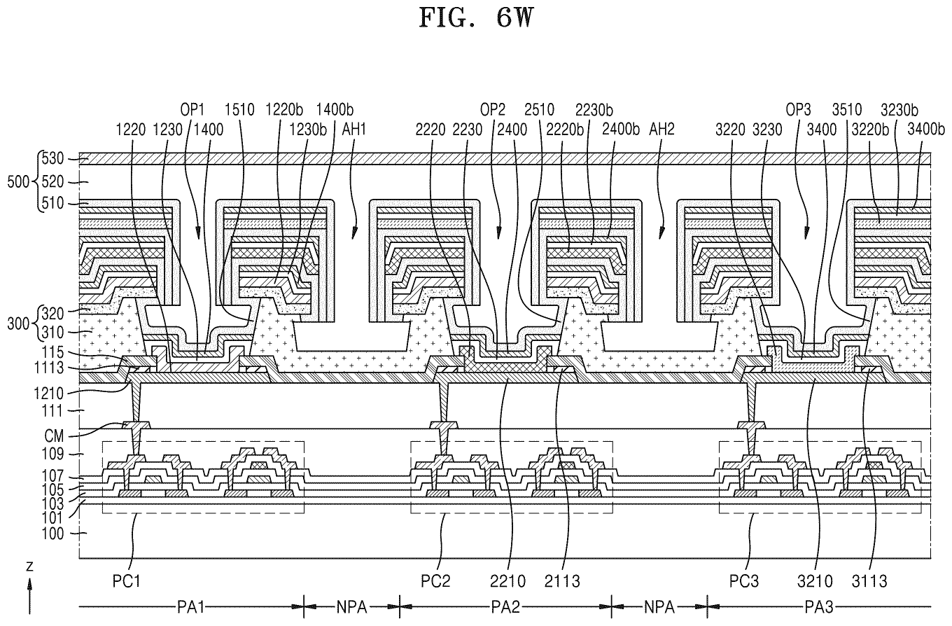

FIGS. 6A to 6W are schematic cross-sectional views showing a process of manufacturing the display apparatus 1 according to an embodiment.

Referring to FIG. 6A, the first to third sub-pixel electrodes 1210, 2210, and 3210 may be formed on the substrate 100. The first to third sub-pixel electrodes 1210, 2210, and 3210 may be respectively arranged in the first to third sub-pixel areas PA1, PA2, and PA3 and be spaced apart from each other. The first to third sub-pixel electrodes 1210, 2210, and 3210 may be simultaneously formed during the same process. The first to third sub-pixel electrodes 1210, 2210, and 3210 may include the same material.

Before the first to third sub-pixel electrodes 1210, 2210, and 3210 are formed, the first to third sub-pixel circuits PC1, PC2, and PC3, the first organic insulating layer 109, the second organic insulating layer 111, and the connection metal CM may be formed between the substrate 100 and the first to third sub-pixel electrodes 1210, 2210, and 3210. In an embodiment, it is shown in FIG. 6A that the first to third sub-pixel circuits PC1, PC2, and PC3 have the same structure as a structure of the sub-pixel circuit PC (see FIG. 3) described with reference to FIG. 3A.

The substrate 100 may include glass or polymer resin, and a buffer layer 101, a first gate insulating layer 103, a first interlayer insulating layer 105, and a second interlayer insulating layer 107 may be disposed on the substrate 100. The buffer layer 101 may prevent impurities from penetrating a semiconductor layer of a transistor, the first gate insulating layer 103 may be between the semiconductor layer and a gate electrode, the first interlayer insulating layer 105 may be between a lower electrode and an upper electrode of a storage capacitor, and the second interlayer insulating layer 107 may be provided to insulate a source electrode/drain electrode of the transistor from the gate electrode. The first to third sub-pixel circuits PC1, PC2, and PC3 may be respectively and electrically connected to the first to third sub-pixel electrodes 1210, 2210, and 3210 through the connection metal CM.

The first to third sub-pixel electrodes 1210, 2210, and 3210 may include a reflective layer including Ag, Mg, Al, Pt, Pd, Au, Ni, Nd, Ir, Cr, or a compound thereof, and a transparent conductive layer including ITO, IZO, ZnO, or In₂O₃. In an embodiment, the first to third sub-pixel electrodes 1210, 2210, and 3210 may have a structure in which an ITO layer, an Ag layer, and an ITO layer are sequentially stacked.

The first to third protective layers 1113, 2113, and 3113 may be formed to respectively overlap the first to third sub-pixel electrodes 1210, 2210, and 3210. The first to third protective layers 1113, 2113, and 3113 may include a conductive oxide such as ITO, IZO, IGZO, ITZO, ZnO, AZO, GZO, ZTO, GTO, and FTO. The first to third protective layers 1113, 2113, and 3113 and the first to third sub-pixel electrodes 1210, 2210, and 3210 may be patterned together during the same process.

The metal bank layer including the first metal layer 310 and the second metal layer 320 may be formed on the first to third protective layers 1113, 2113, and 3113. Before the metal bank layer 300 is formed, the insulating layer 115 may be formed. A material of the insulating layer 115 is the same as that described above with reference to FIG. 3B.

Material layers corresponding to the metal bank layer 300, for example, the first metal layer 310 and the second metal layer 320 on the first metal layer 310 may be formed on the insulating layer 115. The characteristics such as the material and the thickness of the first metal layer 310 and the second metal layer 320 are the same as those described above with reference to FIG. 3C. As an example, the thickness of the first metal layer 310 may be greater than the second metal layer 320.

Referring to FIG. 6B, a photoresist PR including opening areas may be formed on the second metal layer 320. The openings of the photoresist PR may overlap the first sub-pixel area PA. The photoresist PR may be formed by forming a photosensitive material layer on the second metal layer 320 and exposing and developing the photosensitive material layer by using a mask.

However, a partial region of the photoresist PR overlapping the non-sub-pixel area NPA may be formed by using a half-tone mask to form the anchor hole AH (see FIG. 4) described above with reference to FIG. 4. For example, as the anchor hole AH does not pass through the metal bank layer 300 but should be a concave hole that is partially removed, the photoresist PR arranged in a portion of the non-sub-pixel area NPA may be formed to have a low thickness through a half-tone mask. Accordingly, a second thickness H2 of the photoresist PR arranged in a partial region of the non-sub-pixel area NPA may be less than a first thickness H1 of the photoresist PR arranged in the second sub-pixel area PA2 and the third sub-pixel area PA3.

Referring to FIG. 6C, an opening overlapping the first sub-pixel electrode 1210 may be formed by removing a portion of the second metal layer 320, a portion of the first metal layer 310, and a portion of the insulating layer 115 arranged in the first sub-pixel area PA1 by using the photoresist PR as a mask. The opening formed in the first sub-pixel area PA1 may have a through-hole shape passing through the metal bank layer 300 and the insulating layer 115. A process of removing a portion of the metal bank layer 300 and the insulating layer 115 may be performed by an etching process (e.g., a dry etching process). The dry etching processes of removing a portion of the metal bank layer 300 and the insulating layer 115 may be simultaneously performed. In another example, the dry etching process of removing a portion of the metal bank layer 300 and the dry etching process of removing a portion of the insulating layer 115 may be separately performed.

However, during the dry etching process, not only a portion of the metal bank layer 300 and the insulating layer 115 may not be removed, but also a portion of the photoresist PR may be removed together. For example, in FIG. 6C, a first thickness H1′ of the photoresist PR arranged in the second sub-pixel area PA2 may be less than the first thickness H1 in FIG. 6B. Accordingly, the photoresist PR formed by using the half-tone mask arranged in the non-sub-pixel area NPA may be removed (e.g., entirely removed), and a portion of the metal bank layer 300 overlapping the photoresist PR formed by using the half-tone mask may be removed together. For example, as a portion of the first metal layer 310 and a portion of the second metal layer 320 may be removed in also a portion of the non-sub-pixel area NPA, a hole may be formed. However, a hole formed in the non-sub-pixel area NPA may not pass through the metal bank layer 300 but may have a shape of a blind-hole formed by removing only a portion of the first metal layer 310.

Referring to FIG. 6D, a portion of the first metal layer 310 arranged in the first sub-pixel area PA1 may be further removed and a portion of the first protective layer 1113 may be removed together by using the photoresist PR that remains as a mask. Through this, the first opening OP1 having an undercut structure may be formed in the first sub-pixel area PAL. For example, a portion of the second metal layer 320 arranged around the first opening OP1 may include a first tip PT extending to the first opening OP1 from a point (or portion) at which the bottom surface (or lower surface) of the second metal layer 320 contacts the lateral surface of the first metal layer 310. A process of removing a portion of the first metal layer 310 and a portion of the first protective layer 1113 may be performed by an etching process (e.g., a wet etching process). A specific process and structural characteristics of forming the first opening OP1 are the same as those described above with reference to FIGS. 3D to 3H.

For example, as there is a partial region of the non-sub-pixel area NPA in which the photoresist PR is removed (e.g., entirely removed), a portion of the first metal layer 310 may be further removed in the partial region of the non-sub-pixel area NPA. Through this, the first anchor hole AH1 and the second anchor hole AH2 each having an undercut structure may be formed in the non-sub-pixel area NPA. For example, a portion of the second metal layer 320 arranged around the first anchor hole AH1 and the second anchor hole AH2 may include a second tip PT2 extending to the first anchor hole AH1 and the second anchor hole AH2 from a point (or portion) at which the bottom surface (or lower surface) of the second metal layer 320 contacts the lateral surface of the first metal layer 310. However, as the first anchor hole AH1 and the second anchor hole AH2 remove only a portion of the first metal layer 310 but do not pass through the first metal layer 310, the first anchor hole AH1 and the second anchor hole AH2 may still have blind-hole shapes.

Referring to FIG. 6E, the photoresist PR may be removed, and the first intermediate layer 1220 may be formed. As described above with reference to FIG. 3L, the first intermediate layer 1220 may have a multi-layered structure including the first common layer, the emission layer, and/or the second common layer. The first intermediate layer 1220 may be formed by a deposition method such as a thermal deposition.

The first intermediate layer 1220 may be formed on the first sub-pixel electrode 1210 through the first opening OP1 of the metal bank layer 300. The inner portion of the first intermediate layer 1220 may contact (e.g., directly contact) the inner portion of the first sub-pixel electrode 1210, and the outer portion of the first intermediate layer 1220 may be disposed on the insulating layer 115. The outer portion of the first intermediate layer 1220 may not contact (e.g., directly contact) the lateral surface of the first metal layer 310 but may be spaced apart from the first metal layer 310. However, embodiments are not limited thereto, and as shown in FIG. 6G, the outer portion of the first intermediate layer 1220 may contact (e.g., directly contact) the lateral surface of the first metal layer 310 facing the first opening OP1.

As the first intermediate layer 1220 is deposited without a separate mask, materials for forming the first intermediate layer 1220 may be deposited in not only the first sub-pixel area PA1 but also other regions, for example, the second sub-pixel area PA2, the third sub-pixel area PA3, and the non-sub-pixel area NPA. By the structure of the first opening OP1 of the metal bank layer 300 including the first tip PT1, the first intermediate layer 1220 may be separated and spaced apart from the first dummy intermediate layer 1220b disposed on the metal bank layer 300. For example, by the structures of the first anchor hole AH1 and the second anchor hole AH2 of the metal bank layer 300 including the second tip PT2, the first dummy intermediate layer 1220b may be separated and spaced apart from a (1-2)th dummy intermediate layer 1220c deposited in the first anchor hole AH1 and the second anchor hole AH2.

The first intermediate layer 1220, the first dummy intermediate layer 1220b, and the (1-2)th dummy intermediate layer 1220c may include the same material and/or the same number of sub-layers (e.g., the first common layer, the emission layer, and the second common layer).

Referring to FIG. 6F, the first opposite electrode 1230 may be formed on the first intermediate layer 1220. Like the first intermediate layer 1220, the first opposite electrode 1230 may be formed through a deposition method such as a thermal deposition. The first opposite electrode 1230 may overlap the first intermediate layer 1220. During the deposition process, an incident angle of a material forming the first opposite electrode 1230 may be different from an incident angle of a material forming the first intermediate layer 1220. During the process of depositing the first opposite electrode 1230, the outer portion (or the peripheral portion) of the first opposite electrode 1230 may contact (e.g., directly contact) the lateral surface of the first metal layer 310 facing the first opening OP1. For example, the edge portion or the outer portion (or the peripheral portion) of the first opposite electrode 1230 may extend to pass across the edge portion or the outer portion (or the peripheral portion) of the first intermediate layer 1220 and contact (e.g., directly contact) the lateral surface of the first metal layer 310. A material of the first opposite electrode 1230 is the same as that described above with reference to FIG. 3L.

For example, the first capping layer 1400 may be formed on the first opposite electrode 1230. The first capping layer 1400 may overlap the first opposite electrode 1230 in the first opening OP1. A material of the first capping layer 1400 is the same as that described above with reference to FIG. 3K.

As the first opposite electrode 1230 and the first capping layer 1400 are deposited without a separate mask, materials for forming the first opposite electrode 1230 and the first capping layer 1400 may be deposited in not only the first sub-pixel area PA1, but also other regions, for example, the second sub-pixel area PA2, the third sub-pixel area PA3, and the non-sub-pixel area NPA. By the structure of the first opening OP1 of the metal bank layer 300 including the first tip PT1, the first opposite electrode 1230 may be separated and spaced apart from the first dummy opposite electrode 1230b disposed on the metal bank layer 300. For example, by the structures of the first anchor hole AH1 and the second anchor hole AH2 of the metal bank layer 300 including the second tip PT2, the first dummy opposite electrode 1230b may be separated and spaced apart from a (1-2)th dummy opposite electrode 1230c deposited in the first anchor hole AH1 and the second anchor hole AH2. Likewise, a first dummy capping layer 1400b which is a portion of the first capping layer 1400 may be disposed on the first dummy opposite electrode 1230b and the (1-2)th dummy opposite electrode 1230c. The first opposite electrode 1230, the first dummy opposite electrode 1230b, and the (1-2)th dummy opposite electrode 1230c may include the same material.

However, in an embodiment, the first dummy intermediate layer 1220b, the first dummy opposite electrode 1230b, and the first dummy capping layer 1400b may be disposed on not only the second metal layer 320 but may cover the lateral surface of the second metal layer 320. FIG. 6G is an enlarged schematic view of a region B of FIG. 6F. As in FIG. 6G, the outer portion of the first dummy intermediate layer 1220b may extend to cover the lateral surface of the second metal layer 320 facing the first opening OP1. For example, the outer portion of the first dummy opposite electrode 1230b may be disposed on the first dummy intermediate layer 1220b and may extend to overlap the lateral surface of the second metal layer 320 facing the first opening OP1. The outer portion of the first dummy capping layer 1440b may be disposed on the first dummy opposite electrode 1230b and may extend to overlap the lateral surface of the second metal layer 320 facing the first opening OP1.

For example, the outer portions of the first intermediate layer 1220, the first opposite electrode 1230, and the first capping layer 1400 may respectively have thicknesses less than thicknesses of the central portions thereof. Likewise, the outer portions of the first dummy intermediate layer 1220b, the first dummy opposite electrode 1230b, and the first dummy capping layer 1400b may respectively have thicknesses less than thicknesses of the central portions thereof. For example, a thickness TH1′ of the outer portion of the first intermediate layer 1220 contacting (e.g., directly contacting) the lateral surface of the first metal layer 310 may be equal to or less than a half of a thickness TH1 of the central portion of the first intermediate layer 1220. The thickness THY of the outer portion of the first opposite electrode 1230 contacting (e.g., directly contacting) the lateral surface of the first metal layer 310 may be equal to or less than a half of the thickness TH3 of the central portion of the first opposite electrode 1230. The thickness of the outer portion of the first capping layer 1400 overlapping the first metal layer 310 may be equal to or less than the thickness of the central portion of the first capping layer 1400. Likewise, a thickness TH2′ of the outer portion of the first dummy intermediate layer 1220b contacting (e.g., directly contacting) the lateral surface of the second metal layer 320 may be equal to or less than a half of a thickness TH2 of the central portion of the first dummy intermediate layer 1220b. The thickness TH4′ of the outer portion of the first dummy opposite electrode 1230b overlapping the lateral surface of the second metal layer 320 may be equal to or less than a half of the thickness TH4 of the central portion of the first dummy opposite electrode 1230b. The thickness of the outer portion of the first dummy capping layer 1400b overlapping the second metal layer 320 may be equal to or less than the thickness of the central portion of the first dummy capping layer 1400b. For example, the first sub-pixel inorganic encapsulation layer 1510 may be formed on the first capping layer 1400. The first sub-pixel inorganic encapsulation layer 1510 may include at least one inorganic material from among aluminum oxide, titanium oxide, tantalum oxide, hafnium oxide, zinc oxide, silicon oxide, silicon nitride, and silicon oxynitride and be deposited by a chemical vapor deposition. The first sub-pixel inorganic encapsulation layer 1510 having an excellent step coverage may continuously cover the inner surfaces of the first opening OP1, the first anchor hole AH1, and the second anchor hole AH2. Furthermore, the first sub-pixel inorganic encapsulation layer 1510 may completely surround the first dummy intermediate layer 1220b, the first dummy opposite electrode 1230b, and the first capping layer 1400 disposed on the second metal layer 320. For example, the first sub-pixel inorganic encapsulation layer 1510 may overlap all of the upper surface and two opposite lateral surfaces of the first capping layer 1400, two opposite lateral surfaces of the first dummy opposite electrode 1230b, and two opposite lateral surfaces of the first dummy intermediate layer 1220b.

Referring to FIG. 6H, the photoresist PR including opening areas may be formed on the first sub-pixel inorganic encapsulation layer 1510. The openings of the photoresist PR may overlap the second sub-pixel area PA2. As described above, the photoresist PR may be formed by forming a photosensitive material layer disposed on the first sub-pixel inorganic encapsulation layer 1510 and exposing and developing the photosensitive material layer by using a mask.

However, partial regions of the photoresist PR overlapping the first anchor hole AH1 and the second anchor hole AH2 may be formed by using a half-tone mask. For example, to remove the (1-2)th dummy intermediate layer 1220c, the (1-2)th dummy opposite electrode 1230c, and the first capping layer 1400 disposed in the first anchor hole AH1 and the second anchor hole AH2, the photoresist PR overlapping the first anchor hole AH1 and the second anchor hole AH2 may be formed to have a low thickness through a half-tone mask. Accordingly, the thickness of the photoresist PR overlapping the first anchor hole AH1 and the second anchor hole AH2 may be less than the thickness of the photoresist PR arranged in the first sub-pixel area PA1 and the third sub-pixel area PA3.

Referring to FIG. 6I, an opening overlapping the second sub-pixel electrode 2210 may be formed by removing a portion of the first sub-pixel inorganic encapsulation layer 1510, a portion of the first capping layer 1400, a portion of the first dummy opposite electrode 1230b, a portion of the first dummy intermediate layer 1220b, a portion of the second metal layer 320, a portion of the first metal layer 310, and a portion of the insulating layer 115 by using the photoresist PR as a mask. The opening formed in the second sub-pixel area PA2 may have a through-hole shape passing through the metal bank layer 300 and the insulating layer 115. A process of removing portions of the first sub-pixel inorganic encapsulation layer 1510, the first capping layer 1400, the first dummy opposite electrode 1230b, the first dummy intermediate layer 1220b, and the insulating layer 115 may be performed by an etching process (e.g., a dry etching process).

However, as described above, a portion of the photoresist may be removed together during the dry etching process. Accordingly, the photoresist PR overlapping the first anchor hole AH1 and the second anchor hole AH2 and formed by using the half-tone mask may be removed (e.g., entirely removed), and a portion of the material disposed in the first anchor hole AH1 and the second anchor hole AH2 may be removed together. For example, a portion of the first sub-pixel inorganic encapsulation layer 1510, a portion of the first capping layer 1400, a portion of the (1-2)th dummy opposite electrode 1230c, and a portion of the (1-2)th dummy intermediate layer 1220c may be also removed through the dry etching process.

Referring to FIG. 6J, a portion of the first metal layer 310 arranged in the second sub-pixel area PA2 may be further removed and a portion of the second protective layer 2113 may be removed together by using the photoresist PR that remains as a mask. Through this, the second opening OP2 having an undercut structure may be formed in the second sub-pixel area PA2. For example, a portion of the second metal layer 320 arranged around the second opening OP2 may include a first tip PT1 extending to the second opening OP2 from a point (or portion) at which the bottom surface (or lower surface) of the second metal layer 320 contacts the lateral surface of the first metal layer 310. A process of removing a portion of the first metal layer 310 and a portion of the second protective layer 2113 may be performed by an etching process (e.g., a wet etching process). A specific process and structural characteristics of forming the second opening OP2 are the same as those described above with reference to FIGS. 3D to 3H.

For example, as the photoresist PR is removed (e.g., entirely removed) even in a region of the non-sub-pixel area NPA overlapping the first anchor hole AH1 and the second anchor hole AH2, the material disposed in the first anchor hole AH1 and the second anchor hole AH2 may be removed together. For example, a portion of the first sub-pixel inorganic encapsulation layer 1510, a portion of the first capping layer 1400, a portion of the (1-2)th dummy opposite electrode 1230c, and a portion of the (1-2)th dummy intermediate layer 1220c that remain in the first anchor hole AH1 and the second anchor hole AH2 after partially being removed by the dry etching process may be also removed by an etching process (e.g., a wet etching process). In case that the wet etching process is performed, the sizes of the first anchor hole AH1 and the second anchor hole AH2 may increase or remain the same. This may be adjusted through a process condition of the wet etching process.

Referring to FIG. 6K, the photoresist PR may be removed. The photoresist PR may be removed through a strip process or an ashing process. In a comparative example, in the case of patterning the intermediate layer 220 and the opposite electrode 230 through the metal bank layer 300, as there is a region through which the dummy intermediate layer 220b and the dummy opposite electrode 230b are exposed to the outside, moisture transmission occurs in case that the photoresist PR is removed through a strip process. For example, in case that the photoresist PR is removed through an ashing process, the surface of the second metal layer 320 may be damaged. As in FIG. 6J, in the case where the lateral surfaces of each of the first dummy intermediate layer 1220b and the first dummy opposite electrode 1230b respectively facing the first opening OP1 and the first anchor hole AH1 are covered by the first sub-pixel inorganic encapsulation layer 1510, a path through which moisture transmission occurs may be blocked, and defects such as layer floating and the like may be prevented even though a strip process is performed. For example, even though the photoresist PR is removed through an ashing process, as there is no region of the second metal layer 320 which is not covered by the photoresist PR and thus exposed to the outside, defects such as the damage to the surface of the second metal layer 320 may be prevented simultaneously.

Referring to FIG. 6I, the second intermediate layer 2220 may be formed. As described above with reference to FIG. 3L, the second intermediate layer 2220 may have a multi-layered structure including the first common layer, the emission layer, and/or the second common layer. The second intermediate layer 2220 may emit light of a color different from a color of the first intermediate layer 1220. The second intermediate layer 2220 may be formed by a deposition method such as a thermal deposition.

The second intermediate layer 2220 may be formed on the second sub-pixel electrode 2210 through the second opening OP2 of the metal bank layer 300. The inner portion of the second intermediate layer 2220 may contact (e.g., directly contact) the inner portion of the second sub-pixel electrode 2210, and the outer portion of the second intermediate layer 2220 may be disposed on the insulating layer 115.

As the second intermediate layer 2220 is deposited without a separate mask, materials for forming the second intermediate layer 2220 may be deposited in not only the second sub-pixel area PA2 but also other regions, for example, the first sub-pixel area PA1, the third sub-pixel area PA3, and the non-sub-pixel area NPA. By the structure of the second opening OP2 of the metal bank layer 300 including the first tip PT1, the second intermediate layer 2220 may be separated and spaced apart from the second dummy intermediate layer 2220b disposed on the metal bank layer 300. For example, by the structures of the first anchor hole AH1 and the second anchor hole AH2 of the metal bank layer 300 including the second tip PT2, the second dummy intermediate layer 2220b may be separated and apart from a (2-2)th dummy intermediate layer 2220c deposited in the first anchor hole AH1 and the second anchor hole AH2. By the structure of the first opening OP1 of the metal bank layer 300 including the first tip PT1, the second dummy intermediate layer 2220b may be separated and spaced apart from the (2-2)th dummy intermediate layer 2220c disposed in the first opening OP1.

The second intermediate layer 2220, the second dummy intermediate layer 2220b, and the (2-2)th dummy intermediate layer 2220c may include the same material and/or the same number of sub-layers (e.g., the first common layer, the emission layer, and the second common layer).

Referring to FIG. 6M, the second opposite electrode 2230 may be formed on the second intermediate layer 2220. Like the second intermediate layer 2220, the second opposite electrode 2230 may be formed through a deposition method such as a thermal deposition. The second opposite electrode 2230 may overlap the second intermediate layer 2220. During the deposition process, an incident angle of a material forming the second opposite electrode 2230 may be different from an incident angle of a material forming the second intermediate layer 2220. During the process of depositing the second opposite electrode 2230, the outer portion (or the peripheral portion) of the second opposite electrode 2230 may contact (e.g., directly contact) the lateral surface of the first metal layer 310 facing the second opening OP2. For example, the edge portion or the outer portion (or the peripheral portion) of the second opposite electrode 2230 may extend to pass across the edge portion or the outer portion (or the peripheral portion) of the second intermediate layer 2220 and contact (e.g., directly contact) the lateral surface of the first metal layer 310. A material of the second opposite electrode 2230 is the same as that described above with reference to FIG. 3L.

For example, the second capping layer 2400 may be formed on the second opposite electrode 2230. The second capping layer 2400 may overlap the second opposite electrode 2230 in the second opening OP2. A material of the second capping layer 2400 is the same as that described above with reference to FIG. 3K.

As the second opposite electrode 2230 and the second capping layer 2400 are deposited without a separate mask, materials for forming the second opposite electrode 2230 and the second capping layer 2400 may be deposited in not only the second sub-pixel area PA2, but also other regions, for example, the first sub-pixel area PA1, the third sub-pixel area PA3, and the non-sub-pixel area NPA. By the structure of the first opening OP1 of the metal bank layer 300 including the first tip PT1, the second opposite electrode 2230 may be separated and spaced apart from the second dummy opposite electrode 2230b disposed on the metal bank layer 300. For example, by the structures of the first anchor hole AH1 and the second anchor hole AH2 of the metal bank layer 300 including the second tip PT2, the second dummy opposite electrode 2230b may be separated and spaced apart from a (2-2)th dummy opposite electrode 2230c deposited in the first anchor hole AH1 and the second anchor hole AH2. By the structure of the first opening OP1 of the metal bank layer 300 including the first tip PT1, the second dummy opposite electrode 2230b may be separated and spaced apart from the (2-2)th dummy opposite electrode 2230c disposed in the first opening OP1. Likewise, a second dummy capping layer 2400b which is a portion of the second capping layer 2400 may be disposed on the second dummy opposite electrode 2230b and the (2-2)th dummy opposite electrode 2230c. The second opposite electrode 2230, the second dummy opposite electrode 2230b, and the (2-2)th dummy opposite electrode 2230c may include the same material.

For example, the second sub-pixel inorganic encapsulation layer 2510 may be formed on the second capping layer 2400. The second sub-pixel inorganic encapsulation layer 2510 may include at least one inorganic material from among aluminum oxide, titanium oxide, tantalum oxide, hafnium oxide, zinc oxide, silicon oxide, silicon nitride, and silicon oxynitride and be deposited by a chemical vapor deposition. The second sub-pixel inorganic encapsulation layer 2510 having an excellent step coverage may continuously cover the inner surfaces of the second opening OP2, the first anchor hole AH1, and the second anchor hole AH2. Furthermore, the second sub-pixel inorganic encapsulation layer 2510 may surround (e.g., completely surround) the second dummy intermediate layer 2220b, the second dummy opposite electrode 2230b, and the second capping layer 2400 disposed on the second metal layer 320. For example, the second sub-pixel inorganic encapsulation layer 2510 may overlap all of the upper surface and two opposite lateral surfaces of the second capping layer 2400, two opposite lateral surfaces of the second dummy opposite electrode 2230b, two opposite lateral surfaces of the second dummy intermediate layer 2220b, two opposite lateral surfaces of the first capping layer 1400, two opposite lateral surfaces of the first dummy opposite electrode 1230b, and two opposite lateral surfaces of the first dummy intermediate layer 1220b.

Referring to FIG. 6N, the photoresist PR including opening areas may be formed on the second sub-pixel inorganic encapsulation layer 2510. The openings of the photoresist PR may overlap the third sub-pixel area PA3. As described above, the photoresist PR may be formed by forming a photosensitive material layer disposed on the second sub-pixel inorganic encapsulation layer 2510 and exposing and developing the photosensitive material layer by using a mask.

However, partial regions of the photoresist PR overlapping the first opening OP1, the first anchor hole AH1, and the second anchor hole AH2 may be formed by using a half-tone mask. For example, to remove the (2-2)th dummy intermediate layer 2220c, the (2-2)th dummy opposite electrode 2230c, and the second capping layer 2400 disposed in the first opening OP1, the first anchor hole AH1, and the second anchor hole AH2, the photoresist PR overlapping the first opening OP1, the first anchor hole AH1, and the second anchor hole AH2 may be formed to have a low thickness through a half-tone mask. Accordingly, the thickness of the photoresist PR overlapping the first opening OP1, the first anchor hole AH1 and the second anchor hole AH2 may be less than the thickness of the photoresist PR arranged in the second sub-pixel area PA2.

Referring to FIG. 6O, an opening overlapping the third sub-pixel electrode 3210 may be formed by removing a portion of the second sub-pixel inorganic encapsulation layer 2510, a portion of the second capping layer 2400, a portion of the second dummy opposite electrode 2230b, a portion of the second dummy intermediate layer 2220b, a portion of the first dummy opposite electrode 1230b, a portion of the first dummy intermediate layer 1220b, a portion of the second metal layer 320, a portion of the first metal layer 310, and a portion of the insulating layer 115 arranged in the third sub-pixel area PA3 by using the photoresist PR as a mask. The opening formed in the third sub-pixel area PA3 may have a through-hole shape passing through the metal bank layer 300 and the insulating layer 115. The process of removing the portions of the first inorganic encapsulation layer 510, the capping layer 400, the dummy opposite electrode 230b, the dummy intermediate layer 220b, the metal bank layer 300, and the insulating layer 115 may be performed by an etching process (e.g., a dry etching process).

However, as described above, a portion of the photoresist may be removed together during the dry etching process. Accordingly, the photoresist PR overlapping the first opening OP1, the first anchor hole AH1 and the second anchor hole AH2 and formed by using the half-tone mask may be removed (e.g., entirely removed), and a portion of the material disposed in the first opening OP1, the first anchor hole AH1, and the second anchor hole AH2 may be removed together. For example, a portion of the second sub-pixel inorganic encapsulation layer 2510, a portion of the second capping layer 2400, a portion of the (2-2)th dummy opposite electrode 2230c, and a portion of the (2-2)th dummy intermediate layer 2220c that are disposed in the first opening OP1, the first anchor hole AH1 and the second anchor hole AH2 may be also removed through a dry etching process.

Referring to FIG. 6P, a portion of the first metal layer 310 arranged in the third sub-pixel area PA3 may be further removed and a portion of the third protective layer 3113 may be removed together by using the photoresist PR that remains as a mask. Through this, the third opening OP3 having an undercut structure may be formed in the third sub-pixel area PA3. For example, a portion of the second metal layer 320 arranged around the third opening OP3 may include the first tip PT1 extending to the third opening OP3 from a point (or portion) at which the bottom surface (or lower surface) of the second metal layer 320 contacts the lateral surface of the first metal layer 310. A process of removing a portion of the first metal layer 310 and a portion of the third protective layer 313 may be performed by an etching process (e.g., a wet etching process). A specific process and structural characteristics of forming the third opening OP3 are the same as those described above with reference to FIGS. 3D to 3H.

For example, as the photoresist PR is removed (e.g., entirely removed) even in a region overlapping the first opening OP1, the first anchor hole AH1 and the second anchor hole AH2, the material disposed in the first opening OP1, the first anchor hole AH1, and the second anchor hole AH2 may be removed together. For example, a portion of the second sub-pixel inorganic encapsulation layer 2510, a portion of the second capping layer 2400, a portion of the (2-2)th dummy opposite electrode 2230c, and a portion of the (2-2)th dummy intermediate layer 2220c that remain in the first opening OP1, the first anchor hole AH1, and the second anchor hole AH2 after partially being removed by the dry etching process may be also removed by an etching process (e.g., a wet etching process). In case that the wet etching process is performed, the sizes of the first anchor hole AH1 and the second anchor hole AH2 may increase or remain the same. This may be adjusted through a process condition of the wet etching process.

Referring to FIG. 6Q, the photoresist PR may be removed. The photoresist PR may be removed through a strip process or an ashing process. As described above, in the case where the lateral surfaces of each of the second dummy intermediate layer 2220b and the second dummy opposite electrode 2230b respectively facing the second opening OP2 and the anchor hole AH are covered by the second sub-pixel inorganic encapsulation layer 2510, a path through which moisture transmission occurs may be blocked, and defects such as layer floating and the like may be prevented even though a strip process is performed. For example, even though the photoresist PR is removed through an ashing process, as there is no region of the second metal layer 320 which is not covered by the photoresist PR and thus exposed to the outside, defects such as the damage to the surface of the second metal layer 320 may be prevented simultaneously.

Referring to FIG. 6R, the third intermediate layer 3220 may be formed. As described above with reference to FIG. 3L, the third intermediate layer 3220 may have a multi-layered structure including the first common layer, the emission layer, and/or the second common layer. The third intermediate layer 3220 may emit light of a color different from those of the first intermediate layer 1220 and the second intermediate layer 2220. The third intermediate layer 3220 may be formed by a deposition method such as a thermal deposition.

The third intermediate layer 3220 may be formed on the third sub-pixel electrode 3210 through the third opening OP3 of the metal bank layer 300. The inner portion of the third intermediate layer 3220 may contact (e.g., directly contact) the inner portion of the third sub-pixel electrode 3210, and the outer portion of the third intermediate layer 3220 may be disposed on the insulating layer 115.

As the third intermediate layer 3220 is deposited without a separate mask, materials for forming the third intermediate layer 3220 may be deposited in not only the third sub-pixel area PA3 but also other regions, for example, the first sub-pixel area PA1, the second sub-pixel area PA2, and the non-sub-pixel area NPA. By the structure of the third opening OP3 of the metal bank layer 300 including the first tip PT1, the third intermediate layer 3220 may be separated and spaced apart from the third dummy intermediate layer 3220b disposed on the metal bank layer 300. For example, by the structures of the first anchor hole AH1 and the second anchor hole AH2 of the metal bank layer 300 including the second tip PT2, the third dummy intermediate layer 3220b may be separated and spaced apart from a (3-2)th dummy intermediate layer 3220c deposited in the first anchor hole AH1 and the second anchor hole AH2. Furthermore, by the structures of the first opening OP1 and the second opening OP2 of the metal bank layer 300 including the first tip PT1, the third dummy intermediate layer 3220b may be separated and spaced apart from the (3-2)th dummy intermediate layer 3220c deposited in the first opening OP1 and the second opening OP2.

The third intermediate layer 3220, the third dummy intermediate layer 3220b, and the (3-2)th dummy intermediate layer 3220c may include the same material and/or the same number of sub-layers (e.g., the first common layer, the emission layer, and the second common layer).

Referring to FIG. 6S, the third opposite electrode 3230 may be formed on the third intermediate layer 3220. Like the third intermediate layer 3220, the third opposite electrode 3230 may be formed through a deposition method such as a thermal deposition. The third opposite electrode 3230 may overlap the third intermediate layer 3220. During the deposition process, an incident angle of a material forming the third opposite electrode 3230 may be different from an incident angle of a material forming the third intermediate layer 3220. During the process of depositing the third opposite electrode 3230, the outer portion (or the peripheral portion) of the third opposite electrode 3230 may contact (e.g., directly contact) the lateral surface of the first metal layer 310 facing the third opening OP3. For example, the edge portion or the outer portion (or the peripheral portion) of the third opposite electrode 3230 may extend to pass across the edge portion or the outer portion (or the peripheral portion) of the third intermediate layer 3220 and contact (e.g., directly contact) the lateral surface of the first metal layer 310. A material of the third opposite electrode 3230 is the same as that described above with reference to FIG. 3L.

For example, the third capping layer 3400 may be formed on the third opposite electrode 3230. The third capping layer 3400 may overlap the third opposite electrode 3230 in the third opening OP3. A material of the third capping layer 3400 is the same as that described above with reference to FIG. 3K.

As the third opposite electrode 3230 and the third capping layer 3400 are deposited without a separate mask, materials for forming the third opposite electrode 3230 and the third capping layer 3400 may be deposited in not only the third sub-pixel area PA3, but also other regions, for example, the first sub-pixel area PA1, the second sub-pixel area PA2, and the non-sub-pixel area NPA. By the structure of the third opening OP3 of the metal bank layer 300 including the first tip PT1, the third opposite electrode 3230 may be separated and spaced apart from the third dummy opposite electrode 3230b disposed on the metal bank layer 300. For example, by the structures of the first anchor hole AH1 and the second anchor hole AH2 of the metal bank layer 300 including the second tip PT2, the third dummy opposite electrode 3230b may be separated and spaced apart from the (3-2)th dummy opposite electrode 3230c deposited in the first anchor hole AH1 and the second anchor hole AH2. Furthermore, by the structures of the first opening OP1 and the second opening OP2 of the metal bank layer 300 including the first tip PT1, the third dummy opposite electrode 3230b may be separated and spaced apart from the (3-2)th dummy opposite electrode 3230c deposited in the first opening OP1 and the second opening OP2. Likewise, a third dummy capping layer 3400b which is a portion of the third capping layer 3400 may be disposed on the third dummy opposite electrode 3230b and the (3-2)th dummy opposite electrode 3230c. The third opposite electrode 3230, the third dummy opposite electrode 3230b, and the (3-2)th dummy opposite electrode 3230c may include the same material.

For example, the third sub-pixel inorganic encapsulation layer 3510 may be formed on the third capping layer 3400. The third sub-pixel inorganic encapsulation layer 3510 may include at least one inorganic material from among aluminum oxide, titanium oxide, tantalum oxide, hafnium oxide, zinc oxide, silicon oxide, silicon nitride, and silicon oxynitride and be deposited by a chemical vapor deposition. The third sub-pixel inorganic encapsulation layer 3510 having an excellent step coverage may continuously cover the inner surfaces of the third opening OP3, the first anchor hole AH1, and the second anchor hole AH2. Furthermore, the third sub-pixel inorganic encapsulation layer 3510 may completely surround the third dummy intermediate layer 3220b, the third dummy opposite electrode 3230b, and the third capping layer 3400 disposed on the second metal layer 320. For example, the third sub-pixel inorganic encapsulation layer 3510 may overlap all of the upper surface and two opposite lateral surfaces of the third capping layer 3400, two opposite lateral surfaces of the third dummy opposite electrode 3230b, two opposite lateral surfaces of the third dummy intermediate layer 3220b, two opposite lateral surfaces of the second capping layer 2400, two opposite lateral surfaces of the second dummy opposite electrode 2230b, two opposite lateral surfaces of the second dummy intermediate layer 2220b, two opposite lateral surfaces of the first capping layer 1400, two opposite lateral surfaces of the first dummy opposite electrode 1230b, and two opposite lateral surfaces of the first dummy intermediate layer 1220b.

Referring to FIG. 6T, the photoresist PR may be formed on the third sub-pixel inorganic encapsulation layer 3510. As described above, the photoresist PR may be formed by forming a photosensitive material layer disposed on the third sub-pixel inorganic encapsulation layer 3510 and exposing and developing the photosensitive material layer by using a mask.

However, partial regions of the photoresist PR overlapping the first opening OP1, the second opening OP2, the first anchor hole AH1, and the second anchor hole AH2 may be formed by using a half-tone mask. For example, to remove the (3-2)th dummy intermediate layer 3220c, the (3-2)th dummy opposite electrode 3230c, and the third capping layer 3400 disposed in the first opening OP1, the second opening OP2, the first anchor hole AH1, and the second anchor hole AH2, the photoresist PR overlapping the first opening OP1, the second opening OP2, the first anchor hole AH1, and the second anchor hole AH2 may be formed to have a low thickness through a half-tone mask. Accordingly, the thickness of the photoresist PR overlapping the first opening OP1, the second opening OP2, the first anchor hole AH1, and the second anchor hole AH2 may be less than the thickness of the photoresist PR arranged in the third sub-pixel area PA3.

Referring to FIG. 6U, an etching process (e.g., a dry etching process) may be performed by using the photoresist PR as a mask. As described above, a portion of the photoresist may be removed together during the dry etching process. Accordingly, the photoresist PR overlapping the first opening OP1, the second opening OP2, the first anchor hole AH1, and the second anchor hole AH2 and formed by using the half-tone mask may be removed (e.g., entirely removed), and a portion of the material disposed in the first opening OP1, the second opening OP2, the first anchor hole AH1, and the second anchor hole AH2 may be removed together. For example, a portion of the third sub-pixel inorganic encapsulation layer 3510, a portion of the third capping layer 3400, a portion of the (3-2)th dummy opposite electrode 3230c, and a portion of the (3-2)th dummy intermediate layer 3220c that are disposed in the first opening OP1, the second opening OP2, the first anchor hole AH1, and the second anchor hole AH2 may be also removed through a dry etching process.

Referring to FIG. 6V, an etching process (e.g., a dry etching process) may be performed by using the photoresist PR that remains as a mask. As the photoresist PR in a region overlapping the first opening OP1, the second opening OP2, the first anchor hole AH1, and the second anchor hole AH2 may be removed (e.g., entirely removed), a remaining material disposed in the first opening OP1, the second opening OP2, the first anchor hole AH1, and the second anchor hole AH2 may be removed. For example, a portion of the third sub-pixel inorganic encapsulation layer 3510, a portion of the third capping layer 3400, a portion of the (3-2)th dummy opposite electrode 3230c, and a portion of the (3-2)th dummy intermediate layer 3220c that remain in the first opening OP1, the second opening OP2, the first anchor hole AH1, and the second anchor hole AH2 after partially being removed by the dry etching process may be also removed by an etching process (e.g., a wet etching process). In case that the wet etching process is performed, the sizes of the first anchor hole AH1 and the second anchor hole AH2 may increase or may not be changed. This may be adjusted through a process condition of the wet etching process.

For example, the photoresist PR may be removed. The photoresist PR may be removed through a strip process or an ashing process. As described above, in the case where the lateral surfaces of each of the third dummy intermediate layer 3220b and the third dummy opposite electrode 3230b respectively facing the second opening OP2 and the second anchor hole AH2 are covered by the third sub-pixel inorganic encapsulation layer 3510, a path through which moisture transmission occurs may be blocked, and defects such as layer floating and the like may be prevented even though a strip process is performed. For example, even though the photoresist PR is removed through an ashing process, as there is no region of the second metal layer 320 which is not covered by the photoresist PR and thus exposed to the outside, defects such as the damage to the surface of the second metal layer 320 may be prevented simultaneously.

Referring to FIG. 6W, the organic encapsulation layer 520 may be formed to fill the openings OP and the anchor holes AH, and the second inorganic encapsulation layer 530 may be formed on the organic encapsulation layer 520. The materials of the organic encapsulation layer 520 and the second inorganic encapsulation layer 530 are the same as the materials described above with reference to FIG. 3K. The organic encapsulation layer 520 may fill at least a portion of the first to third openings OP1, OP2, and OP3, the first anchor hole AH1, and the second anchor hole AH2, but also planarize the upper surface of the display panel. As the second inorganic encapsulation layer 530 is formed on the organic encapsulation layer 520, the second inorganic encapsulation layer 530 may finally encapsulate the display panel and block moisture and oxygen from the outside.

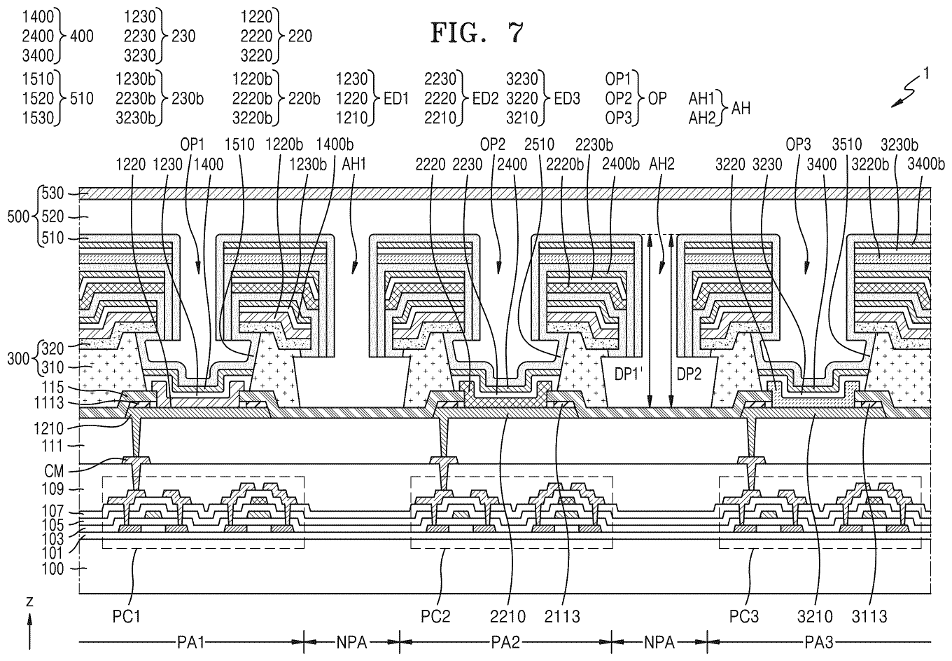

FIG. 7 is a schematic cross-sectional view of the display apparatus 1 according to an embodiment. Referring to FIG. 7, the other characteristics except for the characteristic of the anchor hole AH are the same as those described with reference to FIGS. 4 and 5. Same reference numerals among elements of FIG. 7 are replaced with those previously described with reference to FIGS. 4 and 5, and differences are described below.

Referring to FIG. 7, the metal bank layer 300 may include anchor holes AH arranged in the non-sub-pixel area NPA. As an example, the metal bank layer 300 may include a first anchor hole AH1 and a second anchor hole AH2. The first anchor hole AH1 may be arranged between the first opening OP1 and the second opening OP2, and the second anchor hole AH2 may be arranged between the second opening OP2 and the third opening OP3.

Like the first to third openings OP1, OP2, and OP3, the anchor holes AH may each have a cross-section of an undercut structure. For example, a portion of the second metal layer 320 of the metal bank layer 300 may include a tip extending to a relevant opening of the first anchor hole AH1 and the second anchor hole AH2 from a point (or portion) at which the bottom surface (or lower surface) of the second metal layer 320 contacts the lateral surface of the first metal layer 310.

For example, each of the anchor holes AH may be formed in case that a portion of the metal bank layer 300 is removed in the thickness direction. For example, the anchor hole AH may be formed by passing through the first metal layer 310 and the second metal layer 320. As an example, unlike FIG. 4, the anchor hole AH may have a through-hole shape formed in case that a portion of the metal bank layer 300 is removed (e.g., entirely removed) in the thickness direction.

It may be considered that a depth DP1′ of the anchor hole AH is a sum of a height in the thickness direction of the concave hole formed in case that a portion of the metal bank layer 300 is removed, and a height of a dummy material disposed on the metal bank layer 300. For example, it may be considered that the depth DP1 of the anchor hole AH is a sum of heights in the thickness direction of the metal bank layer 300, the dummy intermediate layers 1220b, 2220b, and 3220b, the dummy opposite electrodes 1230b, 2230b, and 3230b, the dummy capping layers 1400b, 2400b, and 3400b, and the first to third sub-pixel inorganic encapsulation layers 1510, 2510, and 3510. Accordingly, the depth DP1′ of the anchor hole AH may be substantially the same as a sum DP2 of the heights of the metal bank layer 300 and the dummy material disposed on the metal bank layer 300.

The anchor hole AH may expose the upper surface of the insulating layer 115 to the outside. Accordingly, in the case where the organic encapsulation layer 520 fills the openings OP and the anchor holes AH, the upper surface of the insulating layer 115 may contact (e.g., directly contact) the organic encapsulation layer 520 through the anchor hole AH.

The anchor holes AH may prevent a defect such as layer floating. In the case where the anchor holes AH are additionally arranged in the non-sub-pixel area NPA, the undercut structure of the anchor hole AH may disconnect the dummy intermediate layer 220b and the dummy opposite electrode 230b, and thus, prevent a growth of defects such as layer floating.

Furthermore, as the undercut structure of the anchor hole AH forms an unevenness in the thickness direction, the anchor hole AH may hold a cover layer such as the first inorganic encapsulation layer 510, and thus, prevent a defect of layer floating itself. Furthermore, in the case where the anchor hole AH is formed as a through hole passing through the metal bank layer 300, an etching process condition may be more flexibly adjusted during the process of etching the material disposed in the anchor holes AH.

In the display apparatus according to an embodiment, resolution may be improved by patterning light-emitting diodes by using the metal bank layer. Furthermore, the anchor holes may be added to prevent defects such as layer floating, and moisture transmission may be prevented by the encapsulation layer. However, this effect is an example, and the scope of the disclosure is not limited by this effect.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display apparatus comprising:
a first sub-pixel electrode;
a second sub-pixel electrode adjacent to the first sub-pixel electrode;
a metal bank layer including:
a first opening overlapping the first sub-pixel electrode,
a second opening overlapping the second sub-pixel electrode,
a first metal layer, and
a second metal layer disposed on the first metal layer;
a first intermediate layer overlapping the first sub-pixel electrode through the first opening of the metal bank layer;
a second intermediate layer overlapping the second sub-pixel electrode through the second opening of the metal bank layer;
a first opposite electrode disposed on the first intermediate layer through the first opening of the metal bank layer; and
a second opposite electrode disposed on the second intermediate layer through the second opening of the metal bank layer,
wherein the metal bank layer further includes an anchor hole disposed between the first opening and the second opening.

2. The display apparatus of claim 1, further comprising:
an organic encapsulation layer filling at least a portion of each of the first opening, the second opening, and the anchor hole.

3. The display apparatus of claim 2, wherein
the anchor hole is partially removed in a thickness direction of the metal bank layer, and
a depth of the anchor hole is less than a sum of a thickness of the metal bank layer and a thickness of a dummy material on the metal bank layer.

4. The display apparatus of claim 3, wherein
the anchor hole exposes an upper surface of the first metal layer that is partially removed, and
the upper surface of the first metal layer exposed through the anchor hole contacts the organic encapsulation layer.

5. The display apparatus of claim 2, wherein
the anchor hole passes through the metal bank layer, and
a depth of the anchor hole is substantially equal to a sum of a thickness of the metal bank layer and a thickness of a dummy material on the metal bank layer.

6. The display apparatus of claim 5, further comprising:
an insulating layer covering an edge portion of the first sub-pixel electrode and disposed under the metal bank layer, wherein
the anchor hole exposes an upper surface of the insulating layer, and
the upper surface of the insulating layer contacts the organic encapsulation layer through the anchor hole.

7. The display apparatus of claim 1, wherein
a portion of the second metal layer disposed around the first opening includes a tip extending from a portion, at which a lower surface of the second metal layer contacts a lateral surface of the first metal layer, to the first opening,
a portion of the second metal layer disposed around the second opening includes a tip extending from a portion, at which the lower surface of the second metal layer contacts the lateral surface of the first metal layer, to the second opening, and
a portion of the second metal layer disposed around the anchor hole includes a tip extending from a portion, at which the lower surface of the second metal layer contacts the lateral surface of the first metal layer, to the anchor hole.

8. The display apparatus of claim 1, wherein
an outer portion of the first opposite electrode contacts a lateral surface of the first metal layer facing the first opening of the metal bank layer, and
an outer portion of the second opposite electrode contacts a lateral surface of the first metal layer facing the second opening of the metal bank layer.

9. The display apparatus of claim 1, further comprising:
a first dummy intermediate layer disposed on the metal bank layer, the first dummy intermediate layer and the first intermediate layer including a same material;
a first dummy opposite electrode disposed on the first dummy intermediate layer, the first dummy opposite electrode and the first opposite electrode including a same material; and
a first sub-pixel inorganic encapsulation layer covering an inner surface of the first opening,
wherein the first sub-pixel inorganic encapsulation layer continuously extends to overlap an upper surface and two opposite lateral surfaces of the first dummy opposite electrode, and two opposite lateral surfaces of the first dummy intermediate layer.

10. The display apparatus of claim 9, wherein an end portion of the first sub-pixel inorganic encapsulation layer contacts a lateral surface of the metal bank layer facing the anchor hole.

11. The display apparatus of claim 9, further comprising:
a capping layer disposed between a region between the first opposite electrode and the first sub-pixel inorganic encapsulation layer, and
a region between the first dummy opposite electrode and the first sub-pixel inorganic encapsulation layer.

12. The display apparatus of claim 9, further comprising:
a second dummy intermediate layer disposed on the metal bank layer to contact the first sub-pixel inorganic encapsulation layer, the second dummy intermediate layer and the second intermediate layer including a same material;
a second dummy opposite electrode disposed on the second dummy intermediate layer, the second dummy opposite electrode and the second opposite electrode including a same material; and
a second sub-pixel inorganic encapsulation layer covering an inner surface of the second opening,
wherein the second sub-pixel inorganic encapsulation layer continuously extends to overlap an upper surface and two opposite lateral surfaces of the second dummy opposite electrode, two opposite lateral surfaces of the second dummy intermediate layer, two opposite lateral surfaces of the first dummy opposite electrode, and two opposite lateral surfaces of the first dummy intermediate layer.

13. A display apparatus comprising:
a first sub-pixel electrode;
a metal bank layer including:
a first opening overlapping the first sub-pixel electrode,
a first metal layer, and
a second metal layer disposed on the first metal layer;
a first intermediate layer overlapping the first sub-pixel electrode through the first opening of the metal bank layer;
a first opposite electrode disposed on the first intermediate layer through the first opening of the metal bank layer;
a first dummy intermediate layer disposed on the metal bank layer, the first dummy intermediate layer and the first intermediate layer including a same material;
a first dummy opposite electrode on the first dummy intermediate layer, the first dummy opposite electrode and the first opposite electrode including a same material; and
a first sub-pixel inorganic encapsulation layer disposed on the first opposite electrode,
wherein the first sub-pixel inorganic encapsulation layer continuously extends to overlap an inner surface of the first opening, an upper surface and two opposite lateral surfaces of the first dummy opposite electrode, and two opposite lateral surfaces of the first dummy intermediate layer.

14. The display apparatus of claim 13, further comprising:
a second sub-pixel electrode;
a second intermediate layer overlapping the second sub-pixel electrode through a second opening of the metal bank layer;
a second opposite electrode disposed on the second intermediate layer through the second opening of the metal bank layer;
a second dummy intermediate layer disposed on the metal bank layer to contact the first sub-pixel inorganic encapsulation layer, the second dummy intermediate layer and the second intermediate layer including a same material;
a second dummy opposite electrode disposed on the second dummy intermediate layer, the second dummy opposite electrode and the second opposite electrode including a same material; and
a second sub-pixel inorganic encapsulation layer disposed on the second opposite electrode,
wherein the second sub-pixel inorganic encapsulation layer continuously extends to surround an inner surface of the second opening, an upper surface and two opposite lateral surfaces of the second dummy opposite electrode, two opposite lateral surfaces of the second dummy intermediate layer, two opposite lateral surfaces of the first dummy opposite electrode, and two opposite lateral surfaces of the first dummy intermediate layer.

15. The display apparatus of claim 13, wherein an outer portion of the first opposite electrode contacts a lateral surface of the first metal layer facing the first opening of the metal bank layer.

16. The display apparatus of claim 13, wherein a portion of the second metal layer facing the first opening of the metal bank layer includes a tip extending to the first opening from a portion at which a lower surface of the second metal layer contacts a lateral surface of the first metal layer.

17. The display apparatus of claim 14, wherein
the metal bank layer further includes an anchor hole disposed in a non-sub-pixel area in which the first sub-pixel electrode and the second sub-pixel electrode are not disposed, and the anchor hole is disposed between the first opening and the second opening.

18. The display apparatus of claim 17, further comprising:
an organic encapsulation layer filling at least a portion of each of the first opening, the second opening, and the anchor hole,
wherein the organic encapsulation layer is disposed on the first sub-pixel inorganic encapsulation layer and the second sub-pixel inorganic encapsulation layer.

19. The display apparatus of claim 18, wherein
the anchor hole is partially removed in a thickness direction of the metal bank layer, and a depth of the anchor hole is less than a sum of a thickness of the metal bank layer and a thickness of a dummy material on the metal bank layer.

20. The display apparatus of claim 19, wherein
the anchor hole exposes an upper surface of the first metal layer that is partially removed, and
the upper surface of the first metal layer exposed through the anchor hole contacts the organic encapsulation layer.

21. The display apparatus of claim 18, wherein
the anchor hole passes through the metal bank layer, and
a depth of the anchor hole is substantially equal to a sum of a thickness of the metal bank layer and a thickness of a dummy material on the metal bank layer.

22. The display apparatus of claim 21, further comprising:
an insulating layer covering an edge portion of the first sub-pixel electrode and disposed under the metal bank layer, wherein
the anchor hole exposes an upper surface of the insulating layer, and
the upper surface of the insulating layer contacts the organic encapsulation layer through the anchor hole.

23. The display apparatus of claim 14, further comprising:
a capping layer disposed in each of a region between the first opposite electrode and the first sub-pixel inorganic encapsulation layer, a region between the first dummy opposite electrode and the first sub-pixel inorganic encapsulation layer, a region between the second opposite electrode and the second sub-pixel inorganic encapsulation layer, and a region between the second dummy opposite electrode and the second sub-pixel inorganic encapsulation layer.
